(19) United States
(12) Patent Application Publication
(10) Pub. No.: US 2025/0379556 A1
(43) Pub. Date: Dec. 11, 2025

(54) PIEZOELECTRIC RESONATOR

(71) Applicant: Murata Manufacturing Co., Ltd., Nagaokakyo-shi (JP)

(72) Inventor: Toshio NISHIMURA, Nagaokakyo-shi (JP)

(21) Appl. No.: 19/300,803

(22) Filed: Aug. 15, 2025

Related U.S. Application Data
(63) Continuation of application No. PCT/JP2023/042073, filed on Nov. 22, 2023.

(30) Foreign Application Priority Data
Apr. 14, 2023 (JP) 2023-066681

(51) Int. Cl. H03H 9/19; H03H 9/02; H03H 9/05; H03H 9/10; H03H 9/13

(52) U.S. Cl. CPC H03H 9/19; H03H 9/02086; H03H 9/0542; H03H 9/1021; H03H 9/132

(57) ABSTRACT

A piezoelectric resonator includes: a piezoelectric element and an excitation electrode. According to some exemplary aspects, the excitation electrode includes a center portion in a plan view in a thickness direction of the piezoelectric element, the center portion is configured to form a high acoustic velocity region in the piezoelectric resonator. Further, the excitation electrode includes a first end portion and a second end portion at opposite sides of the center portion in a first direction intersecting the thickness direction. The first end portion and the second end portion are configured to form a first low acoustic velocity region and a second low acoustic velocity region on opposite sides of the high acoustic velocity region in the first direction with a lower acoustic velocity than the high acoustic velocity region. Also, some size requirements are provided for the piezoelectric resonator to improve performance.

### CROSS REFERENCE TO RELATED APPLICATIONS

This application is a continuation of International Application No. PCT/JP2023/042073, filed Nov. 22, 2023, which claims priority to Japanese Patent Application No. 2023-066681, filed Apr. 14, 2023, the entire contents of each of which are hereby incorporated by reference in their entirety.

### TECHNICAL FIELD

The present application relates to a piezoelectric resonator.

### BACKGROUND

In various electronic devices such as mobile communication terminals, communication base stations, and home appliances, piezoelectric resonators are used for applications of timing devices, sensors, oscillators, and the like. The piezoelectric resonator includes a piezoelectric element having a pair of main surfaces, and a pair of excitation electrodes provided on the pair of main surfaces of the piezoelectric element.

For example, an example circuit, as described in International Publication No. WO 98/38736, discloses a configuration that reduces spurious oscillations, which are vibrations occurring at frequencies other than the frequency of the main vibration, by flattening a shape of a vibration displacement while changing a mesa thickness ratio of an inverted mesa shape of the excitation electrodes.

### SUMMARY OF INVENTION

However, in the technique in the related art, it is desired to further reduce spurious oscillations and improve an electromechanical coupling coefficient.

Accordingly, the present disclosure has been made in view of the above circumstances, and an object of the present disclosure is to provide a piezoelectric resonator with an improved electromechanical coupling coefficient.

According to an exemplary aspect of the present disclosure, a piezoelectric resonator is provided that includes a piezoelectric element and an excitation electrode that overlaps the piezoelectric element in a thickness direction of the piezoelectric element. According to some exemplary aspects, the excitation electrode includes a center portion in a plan view in the thickness direction, the center portion being configured to form a high acoustic velocity region in the piezoelectric resonator. Further, the excitation electrode includes a first end portion and a second end portion at opposite sides of the center portion in a first direction intersecting the thickness direction. The first end portion and the second end portion are configured to form a first low acoustic velocity region and a second low acoustic velocity region on opposite sides of the high acoustic velocity region in the first direction with a lower acoustic velocity than the high acoustic velocity region. Also, the excitation electrode is configured that a first length of the excitation electrode in the first direction (Ea), a length of the first low acoustic velocity region in the first direction (Wa1), and a length of the second low acoustic velocity region in the first direction (Wa2) satisfy relationships of 0.20≤Wa1/Ea, 0.20≤Wa2/Ea, and 0.5≤(Wa1+Wa2)/Ea≤0.96.

According to another aspect of the present disclosure, a piezoelectric resonator is provided that includes a piezoelectric element; and an excitation electrode that overlaps the piezoelectric element in a thickness direction, in which the piezoelectric resonator includes a high acoustic velocity region and a low acoustic velocity region having an acoustic velocity lower than an acoustic velocity of the high acoustic velocity region, the high acoustic velocity region is provided in a region that overlaps a center portion of the excitation electrode in plan view in the thickness direction, the low acoustic velocity region includes a first low acoustic velocity region, a second low acoustic velocity region, a third low acoustic velocity region, and a fourth low acoustic velocity region that are provided in regions overlapping end portions of the excitation electrode and surrounding the high acoustic velocity region in plan view in the thickness direction, in a first direction that intersects with the thickness direction, the first low acoustic velocity region is adjacent to the high acoustic velocity region, and the second low acoustic velocity region is adjacent to the high acoustic velocity region on a side opposite to the first low acoustic velocity region, in a second direction that intersects with the thickness direction and the first direction, the third low acoustic velocity region is adjacent to the high acoustic velocity region, and the fourth low acoustic velocity region is adjacent to the high acoustic velocity region on a side opposite to the third low acoustic velocity region, and assuming that a length of the excitation electrode in the first direction is Ea, a length of the excitation electrode in the second direction is Eb, a length of each of the first low acoustic velocity region and the second low acoustic velocity region in the first direction is Wa, and a length of each of the third low acoustic velocity region and the fourth low acoustic velocity region in the second direction is Wb, relationships of 0.8<5.0×(Wa/Ea)²+4.0×(Wb/Eb)², Wa/Ea≤0.48, and Wb/Eb≤0.48 are satisfied.

According to the present disclosure, a piezoelectric resonator is provided with an improved electromechanical coupling coefficient.

### BRIEF DESCRIPTION OF DRAWINGS

FIG. 1 is a cross-sectional view of a crystal oscillator according to a first exemplary embodiment.

FIG. 2 is an exploded perspective view of a quartz crystal resonator unit according to the first exemplary embodiment.

FIG. 3 is a cross-sectional view of the quartz crystal resonator unit according to the first exemplary embodiment.

FIG. 4 is a cross-sectional view of a quartz crystal resonator according to the first exemplary embodiment.

FIG. 5 is a plan view of the quartz crystal resonator according to the first exemplary embodiment.

FIG. 6 is a diagram showing simulation results based on the first exemplary embodiment.

FIG. 7 is a diagram showing simulation results based on the first exemplary embodiment.

FIG. 8 is a diagram showing simulation results based on the first exemplary embodiment.

FIG. 9 is a diagram showing simulation results based on the first exemplary embodiment.

FIGS. 10A and 10B are graphs showing an influence of a planar dimension of a low acoustic velocity region.

FIG. 11 is a graph showing an influence of a planar dimension of a low acoustic velocity region.

FIG. 12 is a graph showing an influence of a planar dimension of a low acoustic velocity region.

FIG. 13 is a graph showing an influence of a thickness of a low acoustic velocity region.

FIG. 14 is a graph showing an influence of a thickness of a high acoustic velocity region.

FIG. 15 is a plan view of a quartz crystal resonator according to a second exemplary embodiment.

FIG. 16 is a plan view of a quartz crystal resonator according to a third exemplary embodiment.

FIG. 17 is a plan view of a quartz crystal resonator according to a fourth exemplary embodiment.

FIG. 18 is a cross-sectional view of a quartz crystal resonator according to a fourth exemplary embodiment.

FIG. 19 is a diagram showing simulation results based on the fourth exemplary embodiment.

FIG. 20 is a diagram showing comparison of simulation results based on the first exemplary embodiment and the fourth exemplary embodiment.

FIG. 21 is a graph showing an influence of a planar dimension of a hole.

FIG. 22 is a graph showing influences of planar dimensions and pitches of holes.

FIG. 23 is a graph showing influences of planar dimensions and pitches of holes.

FIG. 24 is a cross-sectional view of a quartz crystal resonator according to a fifth exemplary embodiment.

FIG. 25 is a diagram showing comparison of simulation results based on the fourth exemplary embodiment and the fifth exemplary embodiment.

FIG. 26 is a cross-sectional view of a quartz crystal resonator according to a sixth exemplary embodiment.

FIG. 27 is a diagram showing simulation results based on the sixth exemplary embodiment.

FIG. 28 is a cross-sectional view of a quartz crystal resonator according to a seventh exemplary embodiment.

FIG. 29 is a cross-sectional view of a quartz crystal resonator according to an eighth exemplary embodiment.

FIG. 30 is a cross-sectional view of a quartz crystal resonator according to a ninth exemplary embodiment.

FIG. 31 is a plan view of a modification example of a high acoustic velocity region according to the fourth exemplary embodiment.

FIG. 32 is a plan view of a modification example of a high acoustic velocity region according to the fourth exemplary embodiment.

FIG. 33 is a plan view of a modification example of a high acoustic velocity region according to the fourth exemplary embodiment.

FIG. 34 is a plan view of a modification example of a high acoustic velocity region according to the fourth exemplary embodiment.

FIG. 35 is a plan view of a modification example of a high acoustic velocity region according to the fourth exemplary embodiment.

### DETAILED DESCRIPTION OF EXEMPLARY EMBODIMENTS

Hereinafter, exemplary embodiments of the present disclosure will be described. In the following description of the drawings, the same or similar components are denoted by the same or similar reference numerals. The drawings are examples, and the dimension and shape of each portion are schematic. The technical scope of the present disclosure should not be interpreted as being limited to the exemplary embodiments.

Each drawing is attached with an orthogonal coordinate system including an X axis, a Y′ axis, and a Z′ axis for convenience, in order to clarify a mutual relationship between the respective drawings and to help understanding of a positional relationship between respective members. The X axis, the Y′ axis, and the Z′ axis correspond to each other in each drawing. The X axis, the Y′ axis, and the Z′ axis respectively correspond to crystallographic axes of a quartz crystal element 11 to be described later. The X axis corresponds to an electric axis (polar axis) of the crystal, the Y axis corresponds to a mechanical axis of the crystal, and the Z axis corresponds to an optical axis of the crystal. The Y′ axis and the Z′ axis are axes obtained by respectively rotating the Y axis and the Z axis around the X axis in a direction from the Y axis to the Z axis by 35° 15′±1′30″.

In the following description, a direction parallel to the X axis is referred to as an “X axis direction”, a direction parallel to the Y′ axis is referred to as a “Y′ axis direction”, and a direction parallel to the Z′ axis is referred to as a “Z′ axis direction”. In addition, a direction of an end of an arrow on the X axis, the Y′ axis, and the Z′ axis is referred to as “positive” or “+ (plus)”, and a direction opposite to the arrow is referred to as “negative” or “− (minus)”. For convenience, the description is made assuming that the +Y′ axis direction is the upward direction and the −Y′ axis direction is the downward direction, but the vertical direction of a quartz crystal resonator 10, a quartz crystal resonator unit 1, and a crystal oscillator 100 is not limited. In addition, a plane specified by the X axis and the Z′ axis is defined as a Z′X plane, and the same applies to a plane specified by other axes.

### First Embodiment

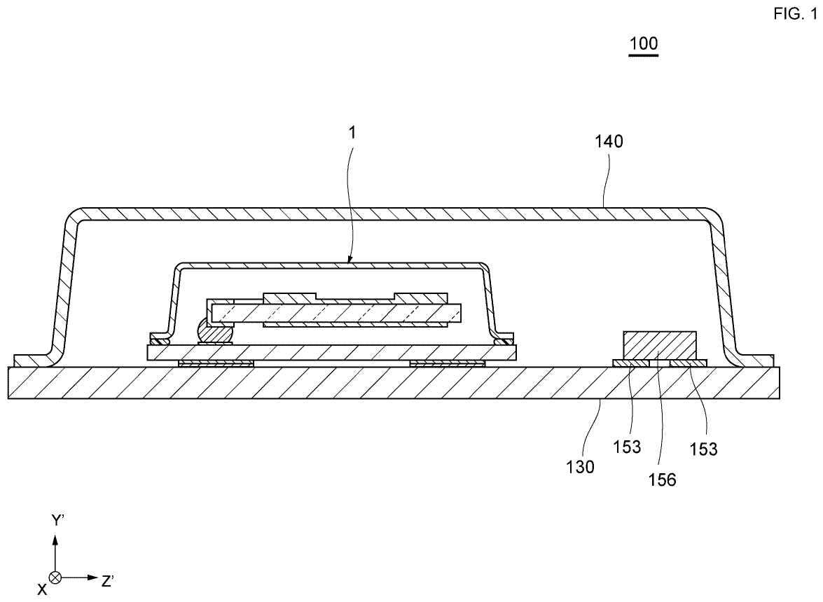

First, a schematic configuration of a crystal oscillator according to an exemplary embodiment will be described with reference to FIG. 1. FIG. 1 is a cross-sectional view of the crystal oscillator according to a first embodiment.

In the following description, as a piezoelectric oscillator, a crystal oscillator (XO) including a quartz crystal resonator unit is taken as an example for description. In addition, as a piezoelectric resonator unit, a quartz crystal resonator unit including a quartz crystal resonator is taken as an example for description. In addition, as a piezoelectric resonator, a quartz crystal resonator including a quartz crystal element is taken as an example for description. The quartz crystal element is a type of piezoelectric body (piezoelectric element) that vibrates according to an applied voltage. The piezoelectric oscillator is not limited to a quartz crystal resonator unit, and may be an oscillator using another piezoelectric body such as ceramic. Similarly, the piezoelectric resonator unit is not limited to a quartz crystal resonator unit, and may be a resonator unit using another piezoelectric body such as ceramic. In addition, similarly, the piezoelectric resonator is not limited to a quartz crystal resonator, and may be an element using another piezoelectric body such as ceramic.

As illustrated in FIG. 1, a crystal oscillator 100 includes a quartz crystal resonator unit 1, a mounting substrate 130, a lid 140, and an electronic component 156.

The quartz crystal resonator unit 1 and the electronic component 156 are accommodated in a space formed between the mounting substrate 130 and the lid 140. The space formed by the mounting substrate 130 and the lid 140 is, for example, airtightly sealed. The space may be airtightly sealed in a vacuum state or may be airtightly sealed in a state of being filled with a gas such as an inert gas.

The mounting substrate 130 is a circuit substrate having a flat plate shape. The mounting substrate 130 includes, for example, a glass epoxy plate and a wiring layer patterned on the glass epoxy plate.

The quartz crystal resonator unit 1 is provided on one surface (an upper surface in FIG. 1) of the mounting substrate 130. More specifically, the quartz crystal resonator unit 1 is electrically coupled to the wiring layer of the mounting substrate 130 by solders 153. The lid 140 includes a bottom cavity that is open on one side (a lower side in FIG. 1). In other words, the lid 140 includes a top wall portion having a flat plate shape, side wall portions that extend from an outer edge of the top wall portion toward the mounting substrate 130, and flange portions that extend from end portions of the side wall portions to the outside. The flange portion is bonded to one surface (the upper surface in FIG. 1) of the mounting substrate 130. Thereby, the quartz crystal resonator unit 1 bonded to the mounting substrate 130 is accommodated in the lid 140. The lid 140 is formed of a metal material, and is formed, for example, by drawing a metal plate.

The electronic component 156 is provided on one surface (the upper surface in FIG. 1) of the mounting substrate 130. More specifically, the wiring layer of the mounting substrate 130 and the electronic component 156 are bonded by the solder 153. Thereby, the electronic component 156 is mounted on the mounting substrate 130.

The electronic component 156 is electrically coupled to the quartz crystal resonator unit 1 via the wiring layer of the mounting substrate 130. The electronic component 156 includes, for example, a capacitor, an IC chip, and the like. The electronic component 156 is, for example, a part of an oscillation circuit that oscillates the quartz crystal resonator unit 1, a part of a temperature compensation circuit that compensates for the temperature characteristics of the quartz crystal resonator unit 1, or the like. In a case where the electronic component 156 includes the temperature compensation circuit, the crystal oscillator 100 corresponds to an example of a temperature compensated crystal oscillator (TCXO). The crystal oscillator 100 may correspond to an example of a voltage controlled crystal oscillator (VCXO) or may correspond to an example of an oven controlled crystal oscillator (OCXO).

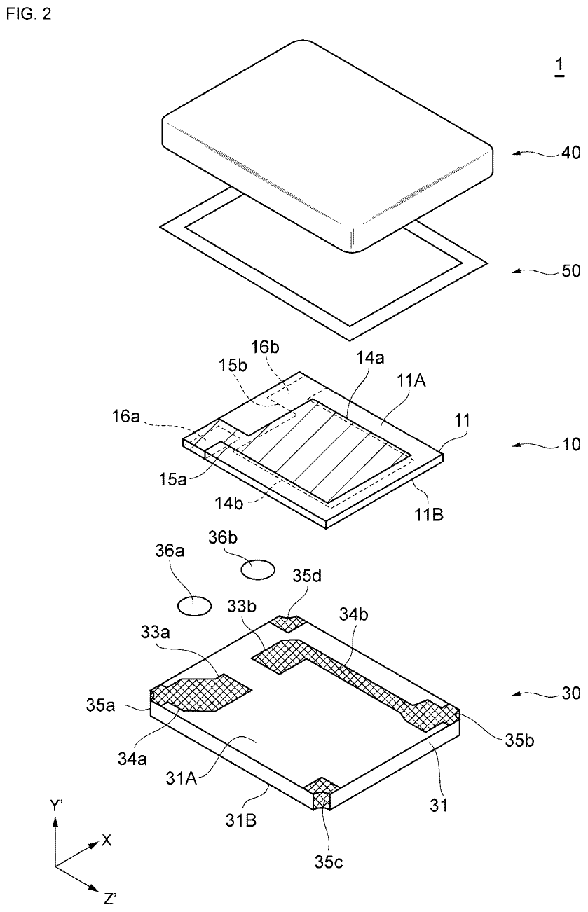

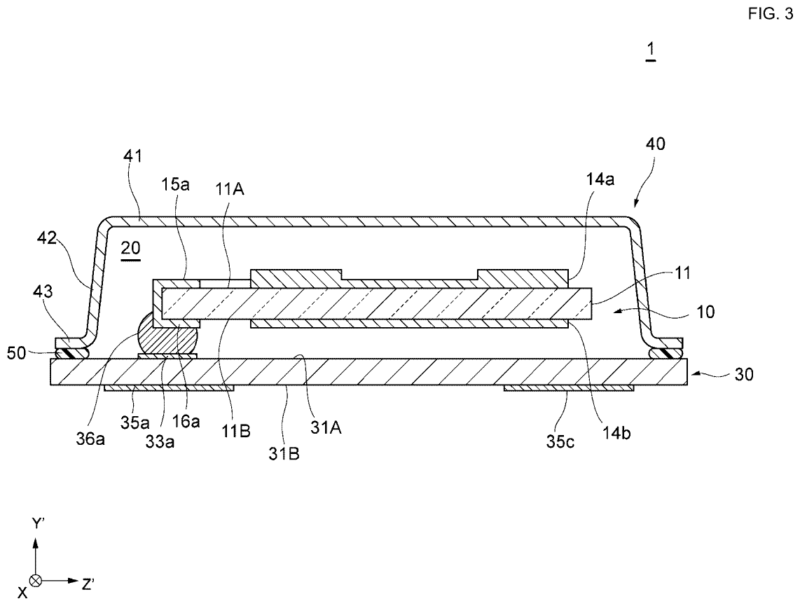

Next, a configuration of the quartz crystal resonator unit 1 according to the first embodiment will be described with reference to FIG. 2 and FIG. 3. FIG. 2 is an exploded perspective view of the quartz crystal resonator unit according to the first embodiment. FIG. 3 is a cross-sectional view of the quartz crystal resonator unit according to the first embodiment.

The Z′ axis direction corresponds to an example of a “first direction”, the X axis direction corresponds to an example of a “second direction”, and the Y′ axis direction corresponds to an example of a “third direction”. The Y′ axis direction corresponds to an example of a “thickness direction”. Here, the first direction, the second direction, and the third direction are not limited to the directions described above. For example, the X axis direction may be the first direction, and the Z′ axis direction may be the second direction.

The quartz crystal resonator unit 1 includes a quartz crystal resonator 10, a base member 30, a lid member 40, and a bonding portion 50.

The quartz crystal resonator 10 is an electromechanical energy conversion element that mutually converts electric energy and mechanical energy by a piezoelectric effect. A frequency of a main mode of the quartz crystal resonator 10 is, for example, approximately 0.8 GHz to 2.0 GHz, and for example, approximately 0.95 GHz. A frequency of an inharmonic mode of the quartz crystal resonator 10 is, for example, within a range of approximately 1% of the frequency of the main mode. The quartz crystal resonator 10 includes a flaky quartz crystal element 11, a first excitation electrode 14a and a second excitation electrode 14b which are included in a pair of excitation electrodes, a first extended electrode 15a and a second extended electrode 15b which are included in a pair of extended electrodes, and a first connection electrode 16a and a second connection electrode 16b which are included in a pair of connection electrodes.

The quartz crystal element 11 has an upper surface 11A and a lower surface 11B that face each other. The upper surface 11A is located on a side that faces the top wall portion 41 of the lid member 40. The lower surface 11B is located on a side that faces the base member 30. The upper surface 11A and the lower surface 11B correspond to a pair of main surfaces of the quartz crystal element 11.

The quartz crystal element 11 is, for example, an AT cut crystal. The AT cut crystal is formed such that the XZ′ plane is the main surface and the thickness is in a direction parallel to the Y′ axis. As an example, when the upper surface 11A is viewed in plan view in the thickness direction (hereinafter, simply referred to as a “plan view”), a shape of the quartz crystal element 11 (hereinafter, referred to as a “planar shape”) is a square shape having a pair of extending sides in the Z′ axis direction and a pair of sides extending in the X axis direction. Further, the quartz crystal element 11 has a thickness in the Y′ axis direction. As an example, the shape of the quartz crystal element 11 is a flat plate shape having a uniform thickness.

The planar shape of the quartz crystal element is not limited to the shape described above. For example, the planar shape of the quartz crystal element may be a rectangular shape having a long side extending in the Z′ axis direction and a short side extending in the X axis direction, and may be a rectangular shape having a short side extending in the Z′ axis direction and a long side extending in the X axis direction. The planar shape of the quartz crystal element may be a polygonal shape, a circular shape, an elliptical shape, or a shape obtained by combining these shapes. Further, the quartz crystal element is not limited to a flat plate shape. The quartz crystal element may have a mesa type structure or an inverted mesa type structure having unevenness on at least one of the upper surface 11A or the lower surface 11B. The quartz crystal element may have a convex structure in which an amount of a change in the thickness changes continuously, or may have a bevel structure in which an amount of a change in the thickness changes discontinuously.

The AT cut quartz crystal element 11 is obtained by being cut out using the XZ′ plane as a main surface when axes obtained by respectively rotating the Y axis and the Z axis, among the X axis, the Y axis, and the Z axis which are crystallographic axes of a synthetic quartz crystal, by 35° 15′±1′30″ around the X axis in the direction from the Y axis to the Z axis are set as the Y′ axis and the Z′ axis.

The quartz crystal resonator 10 using the AT cut quartz crystal element 11 has high frequency stability in a wide temperature range. Further, the AT cut quartz crystal resonator also has excellent aging characteristics, and can be manufactured at low cost. Further, the AT cut quartz crystal resonator uses a thickness shear vibration mode as a main vibration.

The cut-angles of the quartz crystal element are not limited to the angles described above. The rotation angles of the Y′ axis and the Z′ axis in the AT cut quartz crystal element 11 may be tilted in a range of −5° or more and +15° or less from 35° 15′. In addition, as the cut-angles of the quartz crystal element, a different cut other than the AT cut, for example, a BT cut, a GT cut, an SC cut, or the like may be applied.

The first excitation electrode 14a and the second excitation electrode 14b apply an alternating voltage to the quartz crystal element 11 to excite the quartz crystal element 11. The first excitation electrode 14a and the second excitation electrode 14b are provided at the center portion of the quartz crystal element 11 in plan view. The first excitation electrode 14a is provided on the upper surface 11A, and the second excitation electrode 14b is provided on the lower surface 11B. The first excitation electrode 14a and the second excitation electrode 14b face each other in the Y′ axis direction with the quartz crystal element 11 interposed therebetween. The first excitation electrode 14a corresponds to an example of an “excitation electrode”.

A planar shape of the first excitation electrode 14 is a rectangular shape having a short side that extends in the Z′ axis direction and a long side that extends in the X axis direction. Further, the first excitation electrode 14a has a thickness in the Y′ axis direction. The second excitation electrode 14b also has the same shape.

The planar shapes of the first excitation electrode and the second excitation electrode are not limited to the shape described above. The planar shapes of the first excitation electrode and the second excitation electrode may be a rectangular shape having a short side extending in the X axis direction. In addition, the planar shapes of the first excitation electrode and the second excitation electrode may be a square shape, a polygonal shape, a circular shape, an elliptical shape, or a combination thereof.

The first extended electrode 15a electrically couples the first excitation electrode 14a and the first connection electrode 16a, and the second extended electrode 15b electrically couples the second excitation electrode 14b and the second connection electrode 16b. The first extended electrode 15a is provided from the upper surface 11A to the lower surface 11B of the quartz crystal element 11, and the second extended electrode 15b is provided on the lower surface 11B of the quartz crystal element 11.

The first connection electrode 16a and the second connection electrode 16b electrically couple the quartz crystal resonator 10 to the base member 30. The first connection electrode 16a and the second connection electrode 16b are provided on the lower surface 11B of the quartz crystal element 11.

The first excitation electrode 14a, the first extended electrode 15a, and the first connection electrode 16a are integrally provided. The same applies to the second excitation electrode 14b, the second extended electrode 15b, and the second connection electrode 16b. The electrodes of the quartz crystal resonator 10 have, for example, a multi-layer structure provided by laminating a base layer and a surface layer in this order. For example, the base layer is a chromium (Cr) layer having good adhesion to the quartz crystal element 11, and the surface layer is a gold (Au) layer having good chemical stability. The electrodes of the quartz crystal resonator 10 may include aluminum (Al), molybdenum (Mo), or an aluminum-copper alloy (AlCu) including aluminum as a main component. The electrodes of the quartz crystal resonator 10 may have a single layer structure.

The base member 30 holds the quartz crystal resonator 10 such that the quartz crystal resonator 10 is excited. The base member 30 includes a base 31, connection electrodes 33a and 33b, extended electrodes 34a and 34b, outer electrodes 35a, 35b, 35c, and 35d, and conductive holding members 36a and 36b.

The base 31 is a plate-shaped insulator having an upper surface 31A and a lower surface 31B that face each other in the thickness direction. The upper surface 31A and the lower surface 31B correspond to a pair of main surfaces of the base 31. The upper surface 31A is located on a side facing the quartz crystal resonator 10 and the lid member 40, and corresponds to a mounting surface on which the quartz crystal resonator 10 is mounted. From the viewpoint of preventing a thermal stress acting on the quartz crystal resonator 10 from the base 31 due to thermal history such as reflow, according to some exemplary aspects, the base 31 is formed of a heat-resistant material. From the same viewpoint, the base 31 may be formed of a material having a thermal expansion coefficient close to that of the quartz crystal element 11. The base 31 is formed of, for example, a ceramic substrate, a glass substrate, or a crystal substrate.

A corner portion of the base 31 has a notched side surface of which a part is formed in a cylindrically curved surface shape (also referred to as a castellation shape). The shape of the corner portion of the base 31 is not limited thereto. The corner portion of the base may have a notched side surface formed in a prism shape, or may be a substantially-right-angled corner portion without a notch.

The connection electrodes 33a and 33b are electrically coupled to the quartz crystal resonator 10. The connection electrode 33a is electrically coupled to the connection electrode 16a of the quartz crystal resonator 10, and the connection electrode 33b is electrically coupled to the connection electrode 16b of the quartz crystal resonator 10.

The extended electrode 34a electrically couples the connection electrode 33a and the outer electrode 35a, and the extended electrode 34b electrically couples the connection electrode 33b and the outer electrode 35b. The extended electrodes 34a and 34b are provided on the upper surface 31A of the base 31.

The outer electrodes 35a and 35b are outer terminals for electrically coupling the quartz crystal resonator 10 to an outer substrate. The outer electrode 35a electrically couples the first excitation electrode 14a of the quartz crystal resonator 10 to the mounting substrate 130, and the outer electrode 35b electrically couples the second excitation electrode 14b of the quartz crystal resonator 10 to the mounting substrate 130. One electrode of the outer electrodes 35c and 35d is a ground electrode that grounds the lid member 40, and the other electrode of the outer electrodes 35c and 35d is a dummy electrode that is not electrically coupled to the quartz crystal resonator 10 and the lid member 40. Each of the outer electrodes 35a, 35b, 35c, and 35d is continuously provided from the notched side surfaces provided at the four corner portions of the base 31 to the lower surface 31B. In the example illustrated in FIG. 2, the outer electrode 35a and the outer electrode 35b are located at a diagonal angle on the upper surface 31A of the base 31, and the outer electrode 35c and the outer electrode 35d are located at another diagonal angle on the upper surface 31A of the base 31. Here, the outer electrodes 35a, 35b, 35c, and 35d are not limited thereto. Both the outer electrodes 35c and 35d may be ground electrodes, or may be dummy electrodes. The outer electrodes 35c and 35d may be omitted. The outer electrode 35c may be electrically coupled to one of the outer electrodes 35a and 35b, and the outer electrode 35d may be electrically coupled to the other of the outer electrodes 35a and 35b.

The conductive holding members 36a and 36b electrically couple the base member 30 and the quartz crystal resonator 10, and mechanically hold the quartz crystal resonator 10. The conductive holding member 36a electrically couples the first connection electrode 16a of the quartz crystal resonator 10 to the connection electrode 33a of the base member 30. The conductive holding member 36b electrically couples the second connection electrode 16b of the quartz crystal resonator 10 to the connection electrode 33b of the base member 30. The conductive holding members 36a and 36b are cured products of a conductive adhesive including a thermosetting resin, a photocurable resin, or the like. The main component of the conductive holding members 36a and 36b is, for example, a silicone resin. The conductive holding members 36a and 36b include conductive particles, and as the conductive particles, for example, metal particles including silver (Ag) are used.

The main component of the conductive holding members 36a and 36b is not limited to a silicone resin, and may be, for example, an epoxy resin or an acrylic resin. In addition, the conductive particles included in the conductive holding members 36a and 36b are not limited to silver particles, and may be formed of other metals, conductive ceramics, conductive organic materials, and the like. The conductive holding members 36a and 36b may include a conductive polymer.

The lid member 40 forms an internal space 20 in which the quartz crystal resonator 10 is accommodated between the lid member 40 and the base member 30. The lid member 40 includes a top wall portion 41, side wall portions 42 that extend from an outer edge portion of the top wall portion 41 toward the base member 30, and flange portions 43 that extend from the end portion of the mounting substrate 130 to the outside. The top wall portion 41 faces the base member 30 with the quartz crystal resonator 10 interposed therebetween in the Y′ axis direction. The side wall portions 42 surround the quartz crystal resonator 10 at an interval in the XZ′ plane direction. The flange portions 43 are provided in a frame shape in plan view, and are provided to be closest to the base member 30 among the portions of the lid member 40. A material of the lid member 40 is, in some exemplary embodiments, a conductive material, and a metal material having high airtightness. Since the lid member 40 is formed of a conductive material, the lid member 40 has an electromagnetic shield function of reducing electromagnetic waves entering and exiting the internal space 20. From the viewpoint of preventing generation of a thermal stress, according to some exemplary aspects, the material of the lid member 40 is a material having a thermal expansion coefficient close to that of the base member 30, and is, for example, an Fe—Ni—Co alloy of which the thermal expansion coefficient near the room temperature matches that of glass or ceramic over a wide temperature range. The lid member 40 is electrically coupled to at least one of the outer electrodes 35c and 35d by a ground member (not illustrated).

The bonding portion 50 bonds the base member 30 and the lid member 40 to seal the internal space 20. The bonding portion 50 is provided in a frame shape along the entire periphery of the flange portion 43 on the base member 30, and is sandwiched between the lower surface of the flange portion 43 of the lid member 40 and the upper surface 31A of the base member 30. The bonding portion 50 is formed of an insulating material. The bonding portion 50 is formed of, for example, an organic adhesive including an epoxy-based resin, a vinyl-based resin, an acrylic-based resin, an urethane-based resin, or a silicone resin. The material of the bonding portion 50 is not limited to an organic adhesive, and the bonding portion 50 may be formed of an inorganic adhesive such as a silicon-based adhesive including water glass or a calcium-based adhesive including cement. The material of the bonding portion 50 may be glass having a low melting point (for example, lead-boric-acid-based glass, tin-phosphate-based glass, or the like).

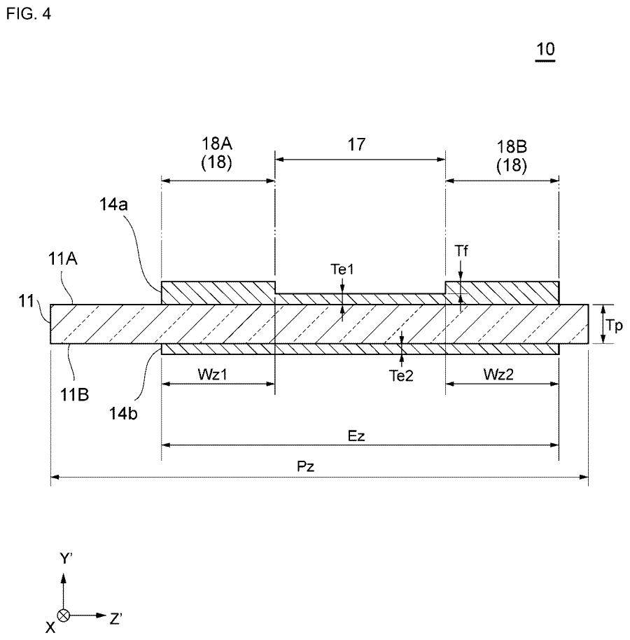

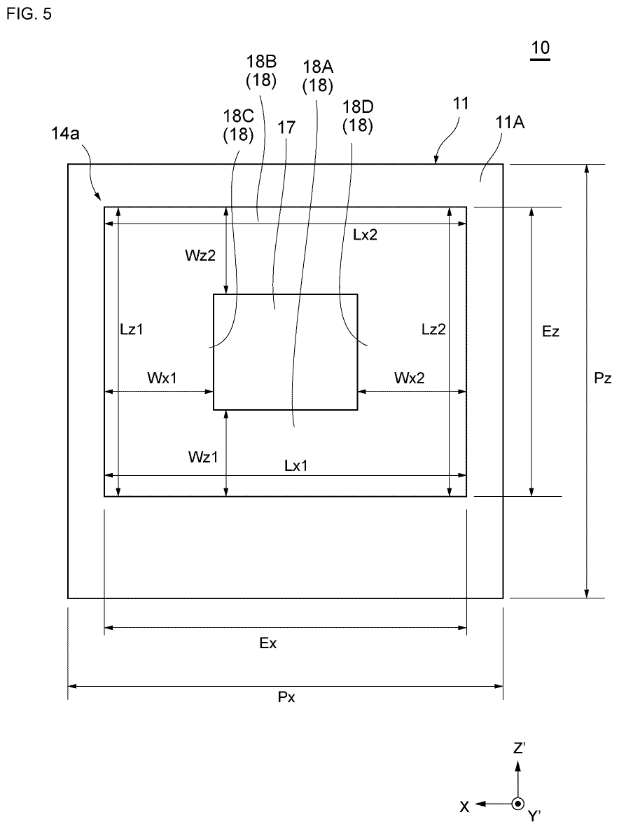

Next, the configuration of the quartz crystal resonator 10 according to the first embodiment will be described with reference to FIG. 4 and FIG. 5. FIG. 4 is a cross-sectional view of the quartz crystal resonator according to the first embodiment. FIG. 5 is a plan view of the quartz crystal resonator according to the first embodiment. For simplification of the description, in FIG. 4 and FIG. 5, the first extended electrode 15a, the second extended electrode 15b, the first connection electrode 16a, and the second connection electrode 16b are omitted.

The quartz crystal resonator 10 is configured to have a high acoustic velocity region 17 and a low acoustic velocity region 18 in a region overlapping the first excitation electrode 14a in plan view. The high acoustic velocity region 17 is a region having a high acoustic velocity in the excitation region. The low acoustic velocity region 18 is a region having a low acoustic velocity in the excitation region, that is, a region having an acoustic velocity lower than the acoustic velocity of the high acoustic velocity region 17.

As illustrated in FIG. 4, the thickness of the quartz crystal element 11 in the high acoustic velocity region 17 is the same as the thickness of the quartz crystal element 11 in the low acoustic velocity region 18. In addition, the thickness of the second excitation electrode 14b in the high acoustic velocity region 17 is the same as the thickness of the second excitation electrode 14b in the low acoustic velocity region 18. However, the thickness of the first excitation electrode 14a in the low acoustic velocity region 18 is thicker than the thickness of the first excitation electrode 14a in the high acoustic velocity region 17. In other words, the high acoustic velocity region 17 is lighter than the low acoustic velocity region 18 by a difference in the thickness of the first excitation electrode 14a. The acoustic velocity of the low acoustic velocity region 18 is lower than the acoustic velocity of the high acoustic velocity region 17 since the mass is added by the difference in the thickness of the first excitation electrode 14a. Thus, according to some exemplary aspects, the high acoustic velocity region and the low acoustic velocity region are defined according to the characteristics or configurations, such as thickness and the like of the excitation electrode, such as the first excitation electrode, the second excitation electrode, and the like.

The reason why the acoustic velocity of the low acoustic velocity region is lower than the acoustic velocity of the high acoustic velocity region is not limited to the difference in the thickness of the first excitation electrode. For example, the reason may be that the thickness of the second excitation electrode in the low acoustic velocity region is thicker than the thickness of the second excitation electrode in the high acoustic velocity region. The reason may be that the thickness of the quartz crystal element in the low acoustic velocity region is thicker than the thickness of the quartz crystal element in the high acoustic velocity region. The reason may be that the material of at least one of the first excitation electrode or the second excitation electrode is different between the low acoustic velocity region and the high acoustic velocity region. The reason may be that a mass addition film for adding the mass is further provided in a region which is at the outer side portion of the high acoustic velocity region and overlaps the low acoustic velocity region in plan view.

As illustrated in FIG. 5, the high acoustic velocity region 17 is provided in a region that overlaps the center portion of the first excitation electrode 14a in plan view. The planar shape of the high acoustic velocity region 17 is a rectangular shape having a long side extending along the X axis direction and a short side extending along the Z′ axis direction.

The planar shape of the high acoustic velocity region is not limited to the shape described above. The planar shape of the high acoustic velocity region may be a rectangular shape having a short side extending along the X axis direction and a long side extending along the Z′ axis direction. Further, the planar shape of the high acoustic velocity region may be a square shape, a polygonal shape, a circular shape, an elliptical shape, or a combination thereof.

As illustrated in FIG. 5, the low acoustic velocity region 18 is provided in a region that overlaps the end portion of the first excitation electrode 14a in plan view. The low acoustic velocity region 18 is provided in a rectangular frame shape that is continuous in the circumferential direction surrounding the center portion of the first excitation electrode 14a. The low acoustic velocity region 18 has a first low acoustic velocity region 18A, a second low acoustic velocity region 18B, a third low acoustic velocity region 18C, and a fourth low acoustic velocity region 18D.

The planar shape of the low acoustic velocity region is not limited to a rectangular frame shape that is continuous in the circumferential direction. The planar shape of the low acoustic velocity region may be a frame shape extending along an outline of a polygonal shape, a circular shape, an elliptical shape, or a shape obtained by combining these shapes. Further, the low acoustic velocity region may have a frame shape that is discontinuous in the circumferential direction.

The first low acoustic velocity region 18A is adjacent to the high acoustic velocity region 17 in the negative Z′ axis direction, and extends along the X axis direction. The second low acoustic velocity region 18B is adjacent to the high acoustic velocity region 17 in the positive Z′ axis direction, and extends along the X axis direction. The third low acoustic velocity region 18C is adjacent to the high acoustic velocity region 17 in the positive X axis direction, and extends along the Z′ axis direction. The fourth low acoustic velocity region 18D is adjacent to the high acoustic velocity region 17 in the negative X axis direction, and extends along the Z′ axis direction. An end portion of the first low acoustic velocity region 18A in the positive X axis direction is connected to an end portion of the third low acoustic velocity region 18C in the negative Z′ axis direction, and an end portion of the first low acoustic velocity region 18A in the negative X axis direction is connected to an end portion of the fourth low acoustic velocity region 18D in the negative Z′ axis direction. An end portion of the second low acoustic velocity region 18B in the positive X axis direction is connected to an end portion of the third low acoustic velocity region 18C in the positive Z′ axis direction, and an end portion of the second low acoustic velocity region 18B in the negative X axis direction is connected to an end portion of the fourth low acoustic velocity region 18D in the positive Z′ axis direction.

In plan view, the end portion of the first low acoustic velocity region 18A in the positive X axis direction overlaps the end portion of the third low acoustic velocity region 18C in the negative Z′ axis direction, and the end portion of the first low acoustic velocity region 18A in the negative X axis direction overlaps the end portion of the fourth low acoustic velocity region 18D in the negative Z′ axis direction. The end portion of the second low acoustic velocity region 18B in the positive X axis direction overlaps the end portion of the third low acoustic velocity region 18C in the positive Z′ axis direction, and the end portion of the second low acoustic velocity region 18B in the negative X axis direction overlaps the end portion of the fourth low acoustic velocity region 18D in the positive Z′ axis direction.

The configuration of the low acoustic velocity region is not limited to the configuration described above. The third low acoustic velocity region and the fourth low acoustic velocity region may be omitted. That is, the high acoustic velocity region, the first low acoustic velocity region, and the second low acoustic velocity region may extend in parallel along the X axis direction, and may be provided in a band shape in plan view from the end portion of the first excitation electrode in the negative X axis direction to the end portion of the first excitation electrode in the positive X axis direction. Further, the first low acoustic velocity region and the second low acoustic velocity region may be omitted. That is, the high acoustic velocity region, the third low acoustic velocity region, and the fourth low acoustic velocity region may extend in parallel along the Z′ axis direction, and may be provided in a band shape in plan view from the end portion of the first excitation electrode in the negative Z′ axis direction to the end portion of the first excitation electrode in the positive Z′ axis direction. Further, the end portion of the first low acoustic velocity region in the positive X axis direction may be separated from the third low acoustic velocity region, and the end portion of the first low acoustic velocity region in the negative X axis direction may be separated from the fourth low acoustic velocity region. The end portion of the second low acoustic velocity region in the positive X axis direction may be separated from the third low acoustic velocity region, and the end portion of the second low acoustic velocity region in the negative X axis direction may be separated from the fourth low acoustic velocity region.

Further, the positional relationship between the first low acoustic velocity region, the second low acoustic velocity region, the third low acoustic velocity region, and the fourth low acoustic velocity region is not limited to the relationship described above. The first low acoustic velocity region may be adjacent to the high acoustic velocity region in the positive Z′ axis direction, and the second low acoustic velocity region may be adjacent to the high acoustic velocity region in the negative Z′ axis direction. The third low acoustic velocity region may be adjacent to the high acoustic velocity region in the negative X axis direction, and the fourth low acoustic velocity region may be adjacent to the high acoustic velocity region in the positive X axis direction. One of the first low acoustic velocity region and the second low acoustic velocity region may be adjacent to the high acoustic velocity region in the negative X axis direction, and the other one of the first low acoustic velocity region and the second low acoustic velocity region may be adjacent to the high acoustic velocity region in the positive X axis direction. One of the third low acoustic velocity region and the fourth low acoustic velocity region may be adjacent to the high acoustic velocity region in the negative Z′ axis direction, and the other one of the third low acoustic velocity region and the fourth low acoustic velocity region may be adjacent to the high acoustic velocity region in the positive Z′ axis direction.

As illustrated in FIG. 4 and FIG. 5, a dimension of the quartz crystal element 11 along the Y′ axis direction is defined as a thickness Tp. A dimension of the first excitation electrode 14a along the Y′ axis direction in the high acoustic velocity region 17 is defined as a thickness Te1. A dimension of the first excitation electrode 14a along the Y′ axis direction in the low acoustic velocity region 18 is defined as a thickness Te1+Tf. A dimension of the second excitation electrode 14b along the Y′ axis direction is defined as a thickness Te2. A dimension of the quartz crystal element 11 along the X axis direction is defined as a length Px, and a dimension of the quartz crystal element 11 along the Z′ axis direction is defined as a length Pz. A dimension of the first excitation electrode 14a along the X axis direction is defined as a length Ex, and a dimension of the first excitation electrode 14a along the Z′ axis direction is defined as a length Ez. A dimension of the first low acoustic velocity region 18A along the Z′ axis direction is defined as a length Wz1. A dimension of the second low acoustic velocity region 18B along the Z′ axis direction is defined as a length Wz2. A dimension of the third low acoustic velocity region 18C along the X axis direction is defined as a length Wx1. A dimension of the fourth low acoustic velocity region 18D along the X axis direction is defined as a length Wx2. A dimension of the first low acoustic velocity region 18A along the X axis direction is defined as a length Lx1. A dimension of the second low acoustic velocity region 18B along the X axis direction is defined as a length Lx2. A dimension of the third low acoustic velocity region 18C along the Z′ axis direction is defined as Lz1. A dimension of the fourth low acoustic velocity region 18D along the Z′ axis direction is defined as a length Lz2.

As illustrated in FIG. 5, in a case where the first low acoustic velocity region 18A has a pair of end portions parallel to the X axis direction in plan view, the length Wz1 is specified by measuring a distance in the Z′ axis direction between the pair of end portions of the first low acoustic velocity region 18A parallel to the X axis direction. In the pair of end portions of the first low acoustic velocity region 18A parallel to the X axis direction, one end portion is a boundary portion between the high acoustic velocity region 17 and the first low acoustic velocity region 18A, and the other end portion is an outer edge portion of the first excitation electrode 14a in the negative Z′ axis direction.

Similarly, the length Wz2 is specified by measuring a distance in the Z′ axis direction between the pair of end portions of the second low acoustic velocity region 18B parallel to the X axis direction. In the pair of end portions of the second low acoustic velocity region 18B parallel to the X axis direction, one end portion is a boundary portion between the high acoustic velocity region 17 and the second low acoustic velocity region 18B, and the other end portion is an outer edge portion of the first excitation electrode 14a in the positive Z′ axis direction.

Similarly, the length Wx1 is specified by measuring a distance in the X axis direction between the pair of end portions of the third low acoustic velocity region 18C parallel to the Z′ axis direction. In the pair of end portions of the third low acoustic velocity region 18C parallel to the Z′ axis direction, one end portion is a boundary portion between the high acoustic velocity region 17 and the third low acoustic velocity region 18C, and the other end portion is an outer edge portion of the first excitation electrode 14a in the positive X axis direction.

Similarly, the length Wx2 is specified by measuring a distance in the X axis direction between the pair of end portions of the fourth low acoustic velocity region 18D parallel to the Z′ axis direction. In the pair of end portions of the fourth low acoustic velocity region 18D parallel to the Z′ axis direction, one end portion is a boundary portion between the high acoustic velocity region 17 and the fourth low acoustic velocity region 18D, and the other end portion is an outer edge portion of the first excitation electrode 14a in the negative X axis direction.

Here, in a case where the planar shape of the high acoustic velocity region 17 is a polygonal shape, a circular shape, an elliptical shape, or a combination thereof, and in a case where the planar shape of the first excitation electrode 14a is a polygonal shape, a circular shape, an elliptical shape, or a combination thereof, when the first low acoustic velocity region 18A does not have a pair of end portions parallel to the X axis direction in plan view, the length Wz1 is specified by a method other than the method described above. For example, the length Wz1 may be specified by dividing an area of the first low acoustic velocity region 18A in plan view by the dimension of the first low acoustic velocity region 18A in the X axis direction. In addition, the length Wz1 may be specified by measuring a plurality of dimensions of the first low acoustic velocity region 18A along the Z′ axis direction at a plurality of positions in the X axis direction and calculating an average value of the plurality of dimensions. In a case of measuring a plurality of dimensions along the Z′ axis direction, the measurement positions of the dimensions along the Z′ axis direction may be determined, for example, at equal intervals in the X axis direction, or may be arbitrarily determined. In addition, the number of the measurement positions of the dimensions along the Z′ axis direction may be arbitrarily determined. When calculating the average value of the plurality of dimensions along the Z′ axis direction, an average value of the remaining dimensions excluding at least one of a maximum value or a minimum value may be calculated. The lengths Wz2, Wx1, and Wx2 may be specified in the same manner as the length Wz1.

As illustrated in FIG. 5, in a case where the first low acoustic velocity region 18A has a pair of end portions parallel to the Z′ axis direction in plan view, the length Lx1 is specified by measuring a distance in the X axis direction between the pair of end portions of the first low acoustic velocity region 18A parallel to the Z′ axis direction. In the pair of end portions of the first low acoustic velocity region 18A parallel to the Z′ axis direction, one end portion is an outer edge portion of the first excitation electrode 14a in the positive X axis direction, and the other end portion is an outer edge portion of the first excitation electrode 14a in the negative X axis direction.

Similarly, the length Lx2 is specified by measuring a distance in the X axis direction between the pair of end portions of the second low acoustic velocity region 18B parallel to the Z′ axis direction. In the pair of end portions of the second low acoustic velocity region 18B parallel to the Z′ axis direction, one end portion is an outer edge portion of the first excitation electrode 14a in the positive X axis direction, and the other end portion is an outer edge portion of the first excitation electrode 14a in the negative X axis direction.

Similarly, the length Lz1 is specified by measuring a distance in the Z′ axis direction between the pair of end portions of the third low acoustic velocity region 18C parallel to the X axis direction. In the pair of end portions of the third low acoustic velocity region 18C parallel to the X axis direction, one end portion is an outer edge portion of the first excitation electrode 14a in the positive Z′ axis direction, and the other end portion is an outer edge portion of the first excitation electrode 14a in the negative Z′ axis direction.

Similarly, the length Lz2 is specified by measuring a distance in the Z′ axis direction between the pair of end portions of the fourth low acoustic velocity region 18D parallel to the X axis direction. In the pair of end portions of the fourth low acoustic velocity region 18D parallel to the X axis direction, one end portion is an outer edge portion of the first excitation electrode 14a in the positive Z′ axis direction, and the other end portion is an outer edge portion of the first excitation electrode 14a in the negative Z′ axis direction.

Here, in a case where the planar shape of the high acoustic velocity region 17 is a polygonal shape, a circular shape, an elliptical shape, or a combination thereof, and in a case where the planar shape of the first excitation electrode 14a is a polygonal shape, a circular shape, an elliptical shape, or a combination thereof, when the first low acoustic velocity region 18A does not have a pair of end portions parallel to the Z′ axis direction in plan view, the length Lx1 is specified by a method other than the method described above. For example, the length Lx1 may be specified by dividing an area of the first low acoustic velocity region 18A in plan view by the dimension of the first low acoustic velocity region 18A in the Z′ axis direction. In addition, the length Lx1 may be specified by measuring a plurality of dimensions of the first low acoustic velocity region 18A along the X axis direction at a plurality of positions in the Z′ axis direction and calculating an average value of the plurality of dimensions. In a case of measuring a plurality of dimensions along the X axis direction, the measurement positions of the dimensions along the X axis direction may be determined, for example, at equal intervals in the Z′ axis direction, or may be arbitrarily determined. In addition, the number of the measurement positions of the dimensions along the X axis direction may be arbitrarily determined. When calculating the average value of the plurality of dimensions along the X axis direction, an average value of the remaining dimensions excluding at least one of a maximum value or a minimum value may be calculated. In addition, the length Lx1 may be specified as the dimension of the first excitation electrode 14a along the X axis direction on a tangent line which is in contact with a boundary between the high acoustic velocity region 17 and the first low acoustic velocity region 18A and extends in the X axis direction. The lengths Lx2, Lz1, and Lz2 may be specified in the same manner as the length Lx1.

The length Ez of the first excitation electrode 14a in the Z′ axis direction corresponds to an example of a “length Ea of the excitation electrode in a first direction”. The length Ex of the first excitation electrode 14a in the X axis direction corresponds to an example of a “length Eb of the excitation electrode in a second direction”. The length Wz1 of the first low acoustic velocity region 18A in the Z′ axis direction corresponds to an example of a “length Wa1 of the first low acoustic velocity region in the first direction”. The length Wz2 of the second low acoustic velocity region 18B in the Z′ axis direction corresponds to an example of a “length Wa2 of the second low acoustic velocity region in the first direction”. The length Wx1 of the third low acoustic velocity region 18C in the X axis direction corresponds to an example of a “length Wb1 of the third low acoustic velocity region in the second direction”. The length Wx2 of the fourth low acoustic velocity region 18D in the X axis direction corresponds to an example of a “length Wb2 of the fourth low acoustic velocity region in the second direction”. The length Lx1 of the first low acoustic velocity region 18A in the X axis direction corresponds to an example of a “length Lb1 of the first low acoustic velocity region in the second direction”. The length Lx2 of the second low acoustic velocity region 18B in the X axis direction corresponds to an example of a “length Lb2 of the second low acoustic velocity region in the second direction”. The length Lz1 of the third low acoustic velocity region 18C in the Z′ axis direction corresponds to an example of a “length La1 of the third low acoustic velocity region in the first direction”. The length Lz2 of the fourth low acoustic velocity region 18D in the Z′ axis direction corresponds to an example of a “length La2 of the fourth low acoustic velocity region in the first direction”.

The lengths Ea, Eb, Wa1, Wa2, Wb1, Wb2, Lb1, Lb2, La1, and La2 are not limited to the lengths described above. For example, the length Wz2 may correspond to the length Wa1, and the length Wz1 may correspond to the length Wa2. The length Wx2 may correspond to the length Wb1, and the length Wx1 may correspond to the length Wb2. In a case where the length Ea corresponds to the length Ex and the length Eb corresponds to the length Ez, one of the lengths Wx1 and Wx2 corresponds to the length Wa1, and the other of the lengths Wx1 and Wx2 corresponds to the length Wa2. One of the lengths Wz1 and Wz2 corresponds to the length Wb1, and the other of the lengths Wz1 and Wz2 corresponds to the length Wb2. Further, the length Lx2 may correspond to the length Lb1, and the length Lx1 may correspond to the length Lb2. The length Lz2 may correspond to the length La1, and the length Lz1 may correspond to the length La2. In a case where the length Ea corresponds to the length Ex and the length Eb corresponds to the length Ez, one of the lengths Lz1 and Lz2 corresponds to the length Lb1, and the other of the lengths Lz1 and Lz2 corresponds to the length Lb2. One of the lengths Lx1 and Lx2 corresponds to the length La1, and the other of the lengths Lx1 and Lx2 corresponds to the length La2.

As described above, the thickness Tp of the quartz crystal element 11 is the same in the high acoustic velocity region 17 and the low acoustic velocity region 18. Similarly, the thickness Te2 of the second excitation electrode 14b is the same in the high acoustic velocity region 17 and the low acoustic velocity region 18. The thickness Te1 of the first excitation electrode 14a in the high acoustic velocity region 17 is, for example, the thickness of the first excitation electrode 14a at the center portion of the high acoustic velocity region 17 when viewed in plan view. The thickness Te1 may be a minimum value, a minimum value, or an average value of the thickness of the first excitation electrode 14a in the high acoustic velocity region 17. The thickness Te1+Tf of the first excitation electrode 14a in the low acoustic velocity region 18 is, for example, the thickness of the first excitation electrode 14a at the center portion of the first low acoustic velocity region 18A, the second low acoustic velocity region 18B, the third low acoustic velocity region 18C, or the fourth low acoustic velocity region 18D. The thickness Te1+Tf may be a maximum value, a minimum value, or an average value of the thickness of the first excitation electrode 14a in the low acoustic velocity region 18. For example, the thickness Te1+Tf may be an average value of the thicknesses of the first excitation electrode 14a at the center portions of each of the first low acoustic velocity region 18A, the second low acoustic velocity region 18B, the third low acoustic velocity region 18C, and the fourth low acoustic velocity region 18D.

In the example illustrated in FIG. 4, the thickness of the first excitation electrode 14a changes in a stepwise manner at the boundary between the high acoustic velocity region 17 and the low acoustic velocity region 18, but the present disclosure is not limited thereto. The thickness of the first excitation electrode 14a may change in a tapered shape, a bevel shape, or a convex shape at the boundary between the high acoustic velocity region 17 and the low acoustic velocity region 18.

In the example illustrated in FIG. 5, the length Wz1 of the first low acoustic velocity region 18A in the Z′ axis direction is substantially equal to the length Wz2 of the second low acoustic velocity region 18B in the Z′ axis direction (Wz1∓Wz2). The sum of the length Wz1 and the length Wz2 is 50% or more of the length Ez of the first excitation electrode 14a in the Z′ axis direction. Further, from the viewpoint of ensuring the high acoustic velocity region 17, the sum of the length Wz1 and the length Wz2 is 96% or less of the length Ez. Further, the length Wz1 may be different from the length Wz2 as long as both the lengths Wz1 and Wz2 are 20% or more of the length Ez. That is, when relationships of 0.2≤Wz1/Ez, 0.2≤Wz2/Ez, and 0.5≤(Wz1+Wz2)/Ez≤0.96 are satisfied, a relationship of Wz1≠Wz2 may be satisfied, and a relationship of Wz1≈Wz2 may be satisfied.

According to some exemplary aspects, both the length Wz1 and the length Wz2 are 25% or more of the length Ez. Further, from the viewpoint of ensuring the high acoustic velocity region 17, for example, both the length Wz1 and the length Wz2 are 48% or less of the length Ez. That is, according to some exemplary aspects, relationships of 0.25≤Wz1/Ez≤0.48 and 0.25≤Wz2/Ez≤0.48 are satisfied. In order to improve the balance of mechanical strength and the like, according to some exemplary aspects, a relationship of Wz1≈Wz2 is satisfied.

Similarly, the length Wx1 of the third low acoustic velocity region 18C in the X axis direction is substantially equal to the length Wx2 of the fourth low acoustic velocity region 18D in the X axis direction (Wx1≈Wx2). The sum of the length Wx1 and the length Wx2 is 50% or more of the length Ex of the first excitation electrode 14a in the X axis direction. Further, from the viewpoint of ensuring the high acoustic velocity region 17, the sum of the length Wx1 and the length Wx2 is 96% or less of the length Ex. Further, the length Wx1 may be different from the length Wx2 as long as both the lengths Wx1 and Wx2 are 20% or more of the length Ex. That is, when relationships of 0.2≤Wx1/Ex, 0.2≤ Wx2/Ex, and 0.5≤(Wx1+Wx2)/Ex≤0.96 are satisfied, a relationship of Wx1≈Wx2 may be satisfied, and a relationship of Wx1≈Wx2 may be satisfied. According to some exemplary aspects, relationships of 0.25≤Wx1/Ex≤0.48 and 0.25≤Wx2/Ex≤0.48 are satisfied, and for example, a relationship of Wx1≈Wx2 is satisfied.

In the example illustrated in FIG. 5, the length Lx1 of the first low acoustic velocity region 18A in the X axis direction and the length Lx2 of the second low acoustic velocity region 18B in the Z axis direction are substantially equal to the length Ex of the first excitation electrode 14a in the X axis direction (Lx1≈Lx2≈Ex). The length Lz1 of the third low acoustic velocity region 18C in the Z′ axis direction and the length Lz2 of the fourth low acoustic velocity region 18D in the Z′ axis direction are substantially equal to the length Ez of the first excitation electrode 14a in the Z′ axis direction (Lz1≈Lz2≈Ez).

The length Lx1 and the length Lx2 may be shorter than the length Ex as long as the first low acoustic velocity region 18A and the second low acoustic velocity region 18B function. That is, in plan view, the end portion of the first low acoustic velocity region 18A in the positive X axis direction may be separated from the end portion of the first excitation electrode 14a in the positive X axis direction toward the negative X axis direction, and the end portion of the first low acoustic velocity region 18A in the negative X axis direction may be separated from the end portion of the first excitation electrode 14a in the negative X axis direction toward the positive X axis direction. However, in order to prevent the vibration form from being disrupted and the waveform from being divided by the first low acoustic velocity region 18A and the second low acoustic velocity region 18B, according to some exemplary aspects, both the length Lx1 and the length Lx2 are set to 80% or more of the length Ex. That is, in some exemplary embodiments, relationships of 0.8≤Lx1/Ex≤1.0 and 0.8≤Lx2/Ex≤1.0 are satisfied.

Similarly, the length Lz1 and the length Lz2 may be shorter than the length Ez as long as the third low acoustic velocity region 18C and the fourth low acoustic velocity region 18D function. That is, in plan view, the end portion of the third low acoustic velocity region 18C in the positive Z′ axis direction may be separated from the end portion of the first excitation electrode 14a in the positive Z′ axis direction toward the negative Z′ axis direction, and the end portion of the fourth low acoustic velocity region 18D in the negative Z′ axis direction may be separated from the end portion of the first excitation electrode 14a in the negative Z′ axis direction toward the positive X axis direction. However, in order to prevent the vibration form from being disrupted and the waveform from being divided by the third low acoustic velocity region 18C and the fourth low acoustic velocity region 18D, according to some exemplary aspects, both the length Lz1 and the length Lz2 are set to 80% or more of the length Ez. That is, in some exemplary embodiments, relationships 0.8≤Lz1/Ez≤1.0 and 0.8≤Lz2/Ez≤1.0 are satisfied.

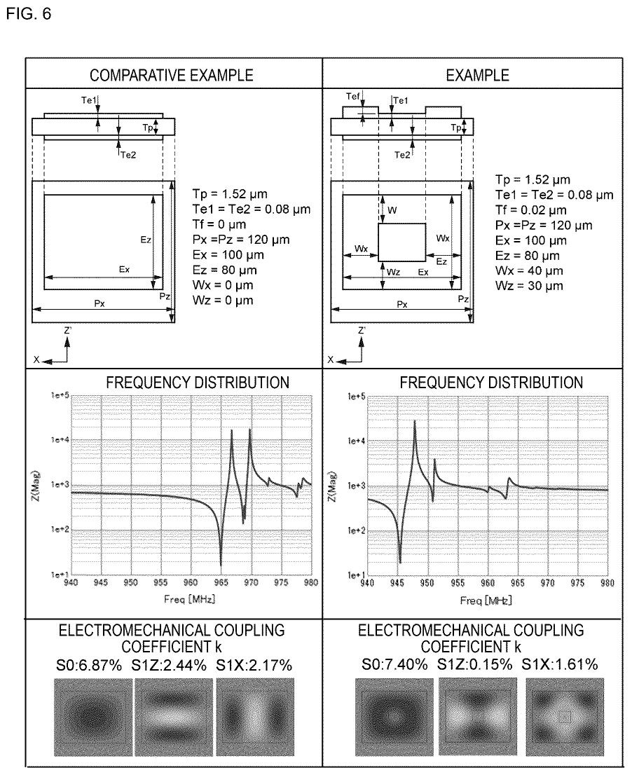

Next, simulation results of examples based on the first embodiment will be described with reference to FIG. 6 to FIG. 9. FIG. 6 to FIG. 9 are diagrams showing simulation results based on the first embodiment. The quartz crystal resonator according to the example has a high acoustic velocity region in which the thickness of the first excitation electrode is Te1 and a low acoustic velocity region in which the thickness of the first excitation electrode is Te1+Tf. In the quartz crystal resonator according to a comparative example, the thickness of the first excitation electrode is uniformly Te1. The gray scale in FIG. 6 to FIG. 9 indicates the magnitude of the displacement. The displacement direction is opposite between a white region and a black region in the gray scale.

### Example

$$\begin{matrix}Tp = 1.52 μm \\ Te 1 = Te 2 = 0.08 μm \\ Tf = 0.02 μm \\ Px = Pz = 120 μm \\ Ex = 100 μm \\ Ez = 80 μm \\ Wx 1 = Wx 2 = W x = 40 μm \\ Wz 1 = Wz 2 = W z = 30 μm\end{matrix}$$

### Comparative Example

$$\begin{matrix}Tp = 1.52 μm \\ Te 1 = Te 2 = 0.08 μm \\ Tf = 0 μm \\ Px = Pz = 120 μm \\ Ex = 100 μm \\ Ez = 80 μm \\ Wx 1 = Wx 2 = Wx = 0 μm \\ Wz 1 = Wz 2 = Wz = 0 μm\end{matrix}$$

As illustrated in FIG. 6, the frequency of the main mode in the example is approximately 945 MHz, and the frequency of the main mode in the comparative example is 965 MHz. An interval between the frequencies of each mode in the example is wider than an interval between the frequencies of each mode in the comparative example. That is, the main mode is easily isolated from the inharmonic mode in the example as compared with the comparative example.

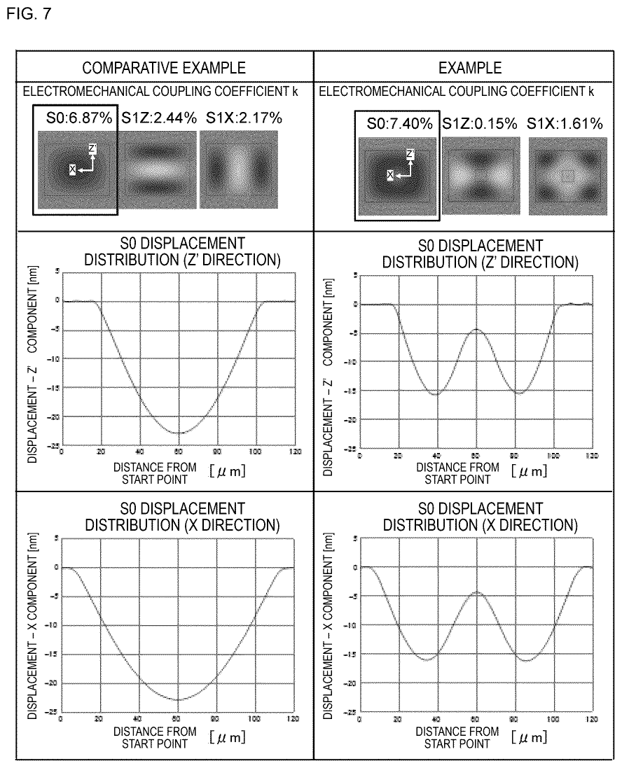

As illustrated in FIG. 7, an electromechanical coupling coefficient k=7.40% in the S0 mode which is the main mode in the example is obtained, and is improved from an electromechanical coupling coefficient k=6.87% in the S0 mode which is the main mode in the comparative example. When comparing S0 displacement distributions of the example and the comparative example, in the low acoustic velocity region, a phase change in the example is faster than a phase change in the comparative example. The S0 displacement distribution in the example is divided at the center portion in both the Z′ axis direction and the X axis direction, and has two local maximums and one local minimum. In the S0 displacement distribution in the example, two local maximums exist in the low acoustic velocity region, and one local minimum exists in the high acoustic velocity region.

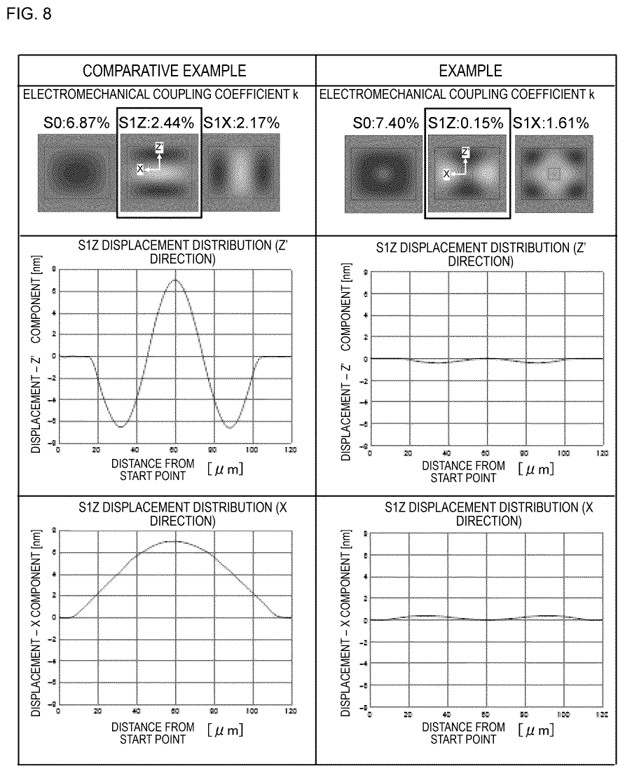

As illustrated in FIG. 8, the electromechanical coupling coefficient k=0.15% in the S1Z mode which is the inharmonic mode in the example is obtained, and is reduced from the electromechanical coupling coefficient k=2.44% in the S1Z mode which is the inharmonic mode in the comparative example. Since the S1 mode has a shorter wavelength in an exaggerated direction than the S0 mode, an influence of the phase change due to the low acoustic velocity region is large. In the comparative example, a vibration region extending in the X axis direction at the center portion in the Z′ axis direction, that is, a white region in the gray scale in FIG. 8, is obtained. In the example, the vibration region is divided at the center portion in the X axis direction, and extends in the Z′ axis direction at the end portion in the X axis direction. Thereby, positive and negative charges are canceled, and the S1Z displacement in the example is prevented in both the Z′ axis direction and the X axis direction.

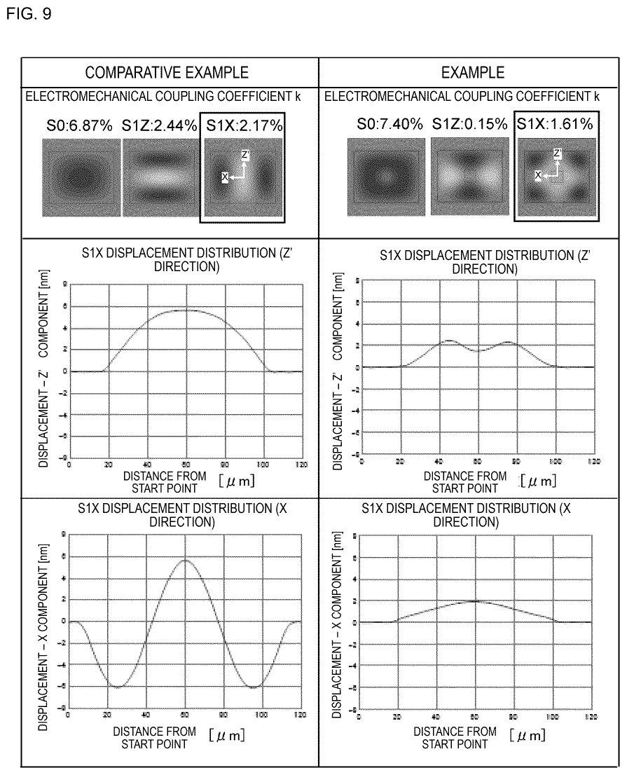

As illustrated in FIG. 9, the electromechanical coupling coefficient k=1.61% in the SIX mode which is the inharmonic mode in the example is obtained, and is reduced from the electromechanical coupling coefficient k=2.17% in the SIX mode which is the inharmonic mode in the comparative example. In the comparative example, a vibration region extending in the Z′ axis direction at the center portion in the X axis direction, that is, a white region in the gray scale in FIG. 9, is obtained. In the example, the vibration region is divided at the center portion in the Z′ axis direction, and extends in the X axis direction. Therefore, in the comparative example, vibration regions extending in the Z′ axis direction at both end portions in the X axis direction, that is, black regions in the gray scale in FIG. 9, are obtained. In the example, the vibration regions are divided into four corners by the white region extending in the X axis direction.

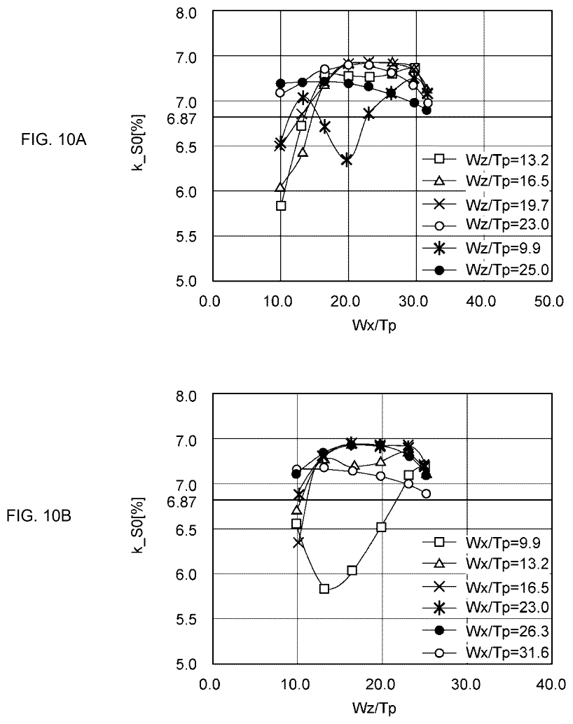

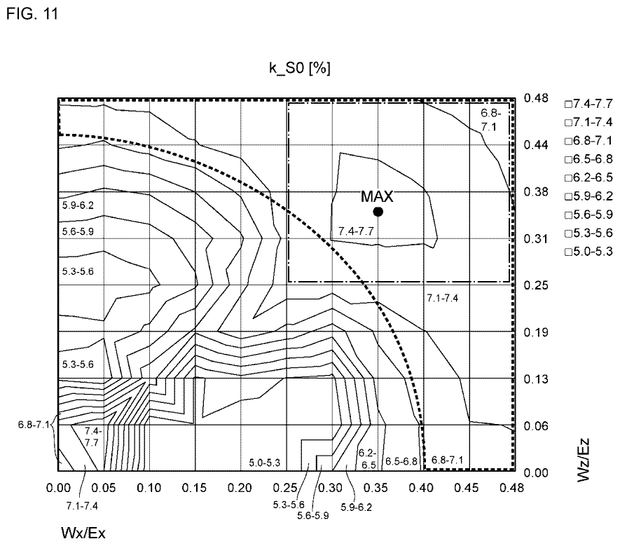

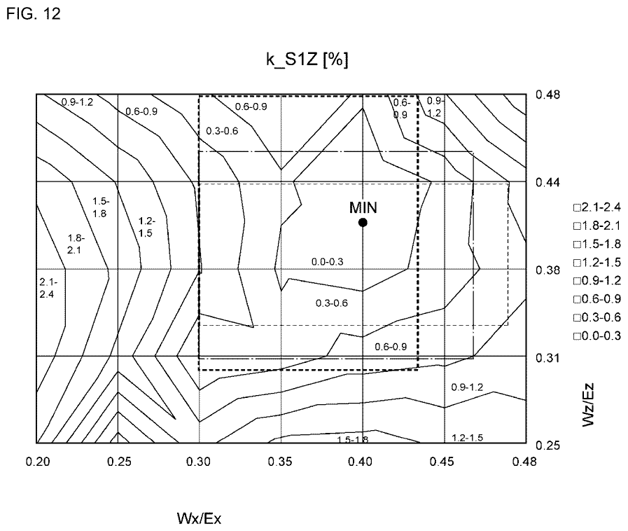

Next, an influence of the dimension of the low acoustic velocity region on the electromechanical coupling coefficient k will be described with reference to FIGS. 10A, 10B to FIG. 12. FIGS. 10A, 10B to FIG. 12 are graphs showing an influence of the planar dimension of the low acoustic velocity region. Based on the first embodiment, Wx1=Wx2=Wx and Wz1=Wz2=Wz are set as variables, and k in the S0 mode and the S1Z mode is calculated. A horizontal axis of a graph in FIG. 10A is Wx/Tp, and a horizontal axis of a graph in FIG. 10B is Wz/Tp. Vertical axes of the graphs in FIGS. 10A and 10B are k in the S0 mode (hereinafter, also referred to as “k_S0”). FIG. 11 is a graph showing a distribution of k_S0 when Wx/Ex is set as the horizontal axis and Wz/Ez is set as the vertical axis. FIG. 12 is a graph showing a distribution of k in the S1Z mode (hereinafter, also referred to as “k_S1Z”) when Wx/Ex is set as the horizontal axis and Wz/Ez is set as the vertical axis. k_S0 and k_S1Z are calculated under the following conditions based on the first embodiment. When Tf=0 μm under the following conditions, k_S0=6.87%.

$$\begin{matrix}Tp = 1.52 μm \\ Te 1 = Te 2 = 0.08 μm \\ Tf = 0.02 μm \\ Px = Pz = 120 μm \\ Ex = 100 μm \\ Ez = 80 μm \\ Wx 1 = Wx 2 = Wx : Variable \\ Wz 1 = Wz 2 = Wz : Variable\end{matrix}$$

As illustrated in FIGS. 10A and 10B, when 16.5≤Wx/Tp and 13.2≤Wz/Tp, that is, 0.25≤Wx/Ex and 0.25≤Wz/Ez, k_S0 is improved from k_S0=6.87% in the comparative example. Further, when Wx/Tp≤31.6 and Wz/Tp≤25.0, that is, Wx/Ex≤0.48 and Wz/Ez≤0.48, k_S0 is improved from k_S0=6.87% in the comparative example.

A one-dotted chain line and a dotted line in the graph of FIG. 11 indicate ranges in which k_S0 is improved from k_S0=6.87% in the comparative example. When the relationships of 0.25≤Wx/Ex≤0.48 and 0.25≤Wz/Ez≤0.48, which are the ranges surrounded by the one-dotted chain line, are satisfied, 7.1%≤k_S0. Further, when the relationships of 0.8<5.0×(Wx/Ex)²+4.0×(Wz/Ez)², Wx/Ex≤0.48, and Wz/Ez≤0.48, which are the ranges surrounded by the dotted line, are satisfied, 6.90%≤k_S0. In particular, when the relationships of Wx/Ex=0.35±0.05 and Wz/Ez=0.35±0.05 are satisfied, k_S0 becomes maximum.

A dotted line in the graph of FIG. 12 indicates a range in which k_S1Z is particularly reduced. When relationships of 0.30≤Wx/Ex≤0.43 and 0.30≤Wz/Ez≤0.48 are satisfied, k_S1Z≤1.0%. When relationships of 0.30≤Wx/Ex≤0.46 and 0.31≤Wz/Ez≤0.46 are satisfied, k_S1Z≤1.0%. When relationships of 0.30≤Wx/Ex≤0.47 and 0.34≤ Wz/Ez≤0.44 are satisfied, k_S1Z≤1.0%. In particular, when relationships of Wx/Ex=0.40±0.05 and Wz/Ez=0.40±0.05 are satisfied, k_S1Z becomes minimum.

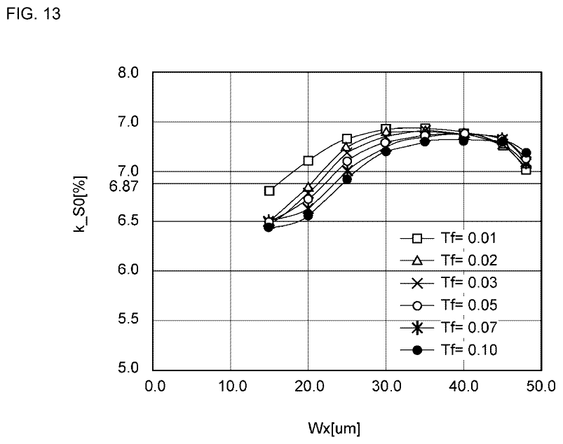

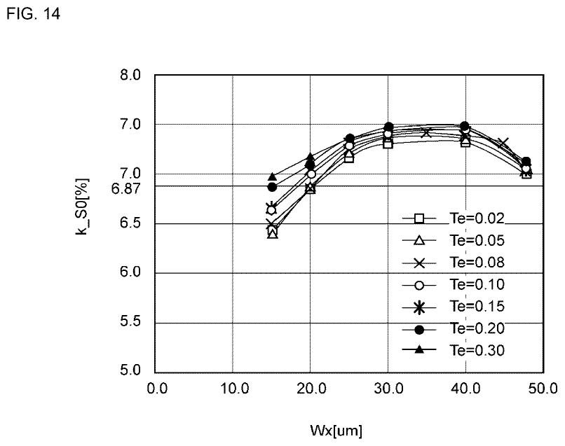

Next, influences of Tf and Te1 on k_S0 will be described with reference to FIG. 13 and FIG. 14. FIG. 13 is a graph showing an influence of the thickness of the low acoustic velocity region. FIG. 14 is a graph showing an influence of the thickness of the high acoustic velocity region.

In the graph of FIG. 13, a horizontal axis indicates Wx, and a vertical axis indicates k_S0 calculated under the following conditions based on the first embodiment. When Tf=0 μm under the following conditions, k_S0=6.87%.

$$\begin{matrix}Tp = 1.52 μm \\ Te 1 = Te 2 = 0.08 μm \\ Tf : 0.01 μm , 0.02 μm , 0.03 μm , 0.05 μm , 0.07 μm , 0.1 μm , \\ Px = Pz = 120 μm \\ Ex = 100 μm \\ Ez = 80 μm \\ Wx 1 = Wx 2 = Wx : Variable \\ Wz 1 = Wz 2 = W z = 30 μm\end{matrix}$$

When a relationship of 25.0≤Wx, that is, 0.25≤Wx/Ex is satisfied, k_S0 is improved and becomes 6.87%<k_S0. In a range of 25.0≤Wx≤48.0, that is, 0.25≤Wx/Ex≤0.48, even in all cases of Tf=0.01 μm, 0.02 μm, 0.03 μm, 0.05 μm, 0.07 μm, and 0.10 μm, k_S0 shows the same tendency with respect to Wx. That is, in a range of 0.01 μm≤Tf≤0.10 μm, that is, 0.125≤Tf/Te1≤1.25, the condition under which k_S0 increases does not depend on Tf, and is 6.87%<k_S0 in the range of 0.25≤Wx/Ex≤0.48.

In the graph of FIG. 14, a horizontal axis indicates Wx, and a vertical axis indicates k_S0 calculated under the following conditions based on the first embodiment. When Te1=Te2=0.05 μm and Tf=0 μm under the following conditions, k_S0=6.87%.

$$\begin{matrix}Tp = 1.52 μm \\ Te 1 = Te 2 = Te : 0.02 μm , 0.05 μm , 0.08 μm , 0.1 μm , 0.15 μm , 0.2 μm , 0.3 μm , \\ Tf = 0.02 μm , \\ Px = Pz = 120 μm \\ Ex = 100 μm \\ Ez = 80 μm \\ Wx 1 = Wx 2 = Wx : Variable \\ Wz 1 = Wz 2 = W z = 30 μm\end{matrix}$$

When a relationship of 20 μm≤Wx≤48 μm, that is, 0.20≤Wx/Ex≤0.48 is satisfied, k_S0 is improved and becomes 6.74%<k_S0. When a relationship of 25 μm≤Wx≤48 μm, that is, 0.25≤Wx/Ex≤0.48 is satisfied, k_S0 is further improved and becomes 7.00%≤k_S0. In a range of 0.20≤Wx/Ex≤0.48, even in all cases of Te=0.02 μm, 0.05 μm, 0.08 μm, 0.10 μm, 0.15 μm, 0.20 μm, and 0.30 μm, k_S0 shows the same tendency with respect to Wx. That is, in a range of 0.02 μm≤Te≤0.30 μm, that is, 0.132≤Te/Tp≤0.197, the condition under which k_S0 is improved does not depend on Te, is 6.87%<k_S0 in a range of 0.20≤Wx/Ex≤0.48, and is 7.00%≤k_S0 in the range of 0.25≤Wx/Ex≤0.48.

As described above, according to the present exemplary embodiment, when the length of the first excitation electrode 14a in the Z′ axis direction is Ez, the length of the first low acoustic velocity region 18A in the Z′ axis direction is Wz1, and the length of the second low acoustic velocity region 18B in the Z′ axis direction is Wz2, relationships of 0.20≤ Wz1/Ez, 0.20≤Wz2/Ez, and 0.50≤(Wz1+Wz2)/Ez≤0.96 are satisfied. According to some exemplary aspects, relationships of 0.25≤Wz1/Ez≤0.48 and 0.25≤Wz2/Ez≤0.48 are satisfied.

Thereby, it is possible to prevent spurious vibration in the Z′ axis direction and improve the electromechanical coupling coefficient k of the main mode.

In addition, according to the present exemplary embodiment, when the length of the first excitation electrode 14a in the X axis direction is Ex, the length of the first low acoustic velocity region 18A in the X axis direction is Wx1, and the length of the second low acoustic velocity region 18B in the X axis direction is Wx2, relationships of 0.20≤Wx1/Ex, 0.20≤Wx2/Ex, and 0.50≤(Wx1+Wx2)/Ex≤0.96 are satisfied. According to some exemplary aspects, relationships of 0.25≤Wx1/Ex≤0.48 and 0.25≤Wx2/Ex≤0.48 are satisfied.

Thereby, it is possible to prevent spurious vibration in the X axis direction and improve the electromechanical coupling coefficient k of the main mode.

In order to prevent spurious vibrations in both the Z′ axis direction and the X axis direction and to further improve the electromechanical coupling coefficient k of the main mode, according to some exemplary aspects, both of relationships of 0.20≤Wz1/Ez, 0.20≤Wz2/Ez, and 0.50≤(Wz1+Wz2)/Ez≤0.96, and relationships of 0.20≤Wx1/Ex, 0.20≤ Wx2/Ex, and 0.50≤(Wx1+Wx2)/Ex≤0.96 are satisfied. According to some exemplary aspects, both of relationships of 0.25≤Wz1/Ez≤0.48 and 0.25≤Wz2/Ez≤0.48 and relationships of 0.25≤Wx1/Ex≤0.48 and 0.25≤Wx2/Ex≤0.48 are satisfied.

Further, according to the present exemplary embodiment, when Wz1=Wz2=Wz and Wx1=Wx2=Wx, the relationships of 0.8<5.0×(Wz/Ez)²+4.0×(Wx/Ex)², Wz/Ez≤0.48, and Wx/Ex≤0.48 are satisfied.

Thereby, it is possible to improve the electromechanical coupling coefficient k of the main mode.

Further, according to the present exemplary embodiment, when the length of the first low acoustic velocity region 18A in the X axis direction is Lx1 and the length of the second low acoustic velocity region 18B in the X axis direction is Lx2, the relationships of 0.8≤Lx1/Ex≤1.0 and 0.8≤Lx2/Ex≤1.0 are satisfied.

Thereby, it is possible to prevent the vibration form from being disrupted and the waveform from being divided by the first low acoustic velocity region 18A and the second low acoustic velocity region 18B.

Further, according to the present exemplary embodiment, when the length of the third low acoustic velocity region 18C in the Z′ axis direction is Lz1 and the length of the fourth low acoustic velocity region 18D in the Z′ axis direction is Lz2, the relationships of 0.8≤Lz1/Ez≤1.0 and 0.8≤Lz2/Ez≤1.0 are satisfied.

Thereby, it is possible to prevent the vibration form from being disrupted and the waveform from being divided by the third low acoustic velocity region 18C and the fourth low acoustic velocity region 18D.

Further, according to the present exemplary embodiment, the relationships of Wx/Ex=0.35±0.05 and Wz/Ez=0.35±0.05 are satisfied.

Thereby, in the ranges of 0.25≤Wz/Ez≤0.48 and 0.25≤Wx/Ex≤0.48, or in the ranges of 0.8<5.0×(Wz/Ez)²+4.0×(Wx/Ex)², Wz/Ez≤0.48, and Wx/Ex≤0.48, the electromechanical coupling coefficient k of the main mode can be maximized.

Further, according to the present exemplary embodiment, the relationships of Wx/Ex=0.40±0.05 and Wz/Ez=0.40±0.05 are satisfied.

Thereby, in the ranges of 0.25≤Wz/Ez≤0.48 and 0.25≤Wx/Ex≤0.48, or in the ranges of 0.8<5.0×(Wz/Ez)²+4.0×(Wx/Ex)², Wz/Ez≤0.48, and Wx/Ex≤0.48, the electromechanical coupling coefficient k of the inharmonic mode S1Z can be minimized.

Further, according to the present exemplary embodiment, the thickness Te1+Tf of the first excitation electrode 14a in the low acoustic velocity region 18 is thicker than the thickness Te1 of the first excitation electrode 14a in the high acoustic velocity region 17.

Thereby, the acoustic velocity of the low acoustic velocity region 18 can be made lower than the acoustic velocity of the high acoustic velocity region 17 due to the difference in the thickness of the first excitation electrode 14a. That is, by further laminating a metal on the end portion of the first excitation electrode 14a or by thinning the center portion of the first excitation electrode 14a by etching or the like, the high acoustic velocity region 17 and the low acoustic velocity region 18 can be formed.

In the present exemplary embodiment, the first excitation electrode 14a has a single layer structure, but the present exemplary embodiment is not limited thereto. For example, by making the first excitation electrode 14a in the low acoustic velocity region 18 have a multi-layer structure, the thickness of the first excitation electrode 14a in the low acoustic velocity region 18 may be thicker than the thickness of the first excitation electrode 14a in the high acoustic velocity region 17. Specifically, a first metal layer having a uniform thickness Te1 may be provided in the high acoustic velocity region 17 and the low acoustic velocity region 18, and a second metal layer having a thickness Tf may be further provided in the low acoustic velocity region 18. The second metal layer may be provided between the first metal layer and the quartz crystal element or may be provided on a side of the first metal layer opposite to the quartz crystal element.

Further, the configuration is not limited to the configuration in which the high acoustic velocity region 17 and the low acoustic velocity region 18 are formed only by the difference in the thickness of the first excitation electrode 14a. For example, by making the thickness of the end portions of the second excitation electrode thicker than the thickness of the center portion, the high acoustic velocity region and the low acoustic velocity region may be formed. Further, the high acoustic velocity region and the low acoustic velocity region may be formed by making the thicknesses of both the end portions of the first excitation electrode and the second excitation electrode thicker than the thickness of the center portion.

Hereinafter, other embodiments will be described. The same or similar configurations as the configurations described in the first embodiment are denoted by the same or similar reference numerals, and descriptions thereof are appropriately omitted. Further, the same operation and effect according to the same configuration will not be sequentially mentioned.

### Second Embodiment

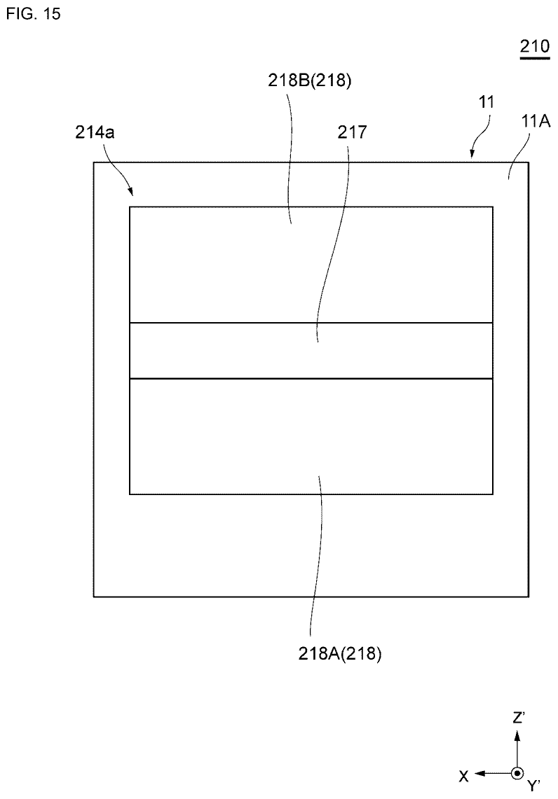

Next, the configuration of the quartz crystal resonator 210 according to the second embodiment will be described with reference to FIG. 15. FIG. 15 is a plan view of the quartz crystal resonator according to the second embodiment.

As illustrated in FIG. 15, the quartz crystal resonator 210 includes a high acoustic velocity region 217, a first low acoustic velocity region 218A, and a second low acoustic velocity region 218B. In plan view, the high acoustic velocity region 217 is provided in a region that is the center portion of the first excitation electrode 214a in the Z′ axis direction and extends in the X axis direction. The first low acoustic velocity region 218A is provided in a region that is adjacent to the high acoustic velocity region 217 in the negative Z′ axis direction and extends in the X axis direction. The second low acoustic velocity region 218B is provided in a region that is adjacent to the high acoustic velocity region 217 in the positive Z′ axis direction and extends in the X axis direction. In plan view, the high acoustic velocity region 217, the first low acoustic velocity region 218A, and the second low acoustic velocity region 218B extend from the end portion of the first excitation electrode 214a in the negative X axis direction to the end portion of the first excitation electrode 214a in the positive X axis direction in a band shape.

### Third Embodiment

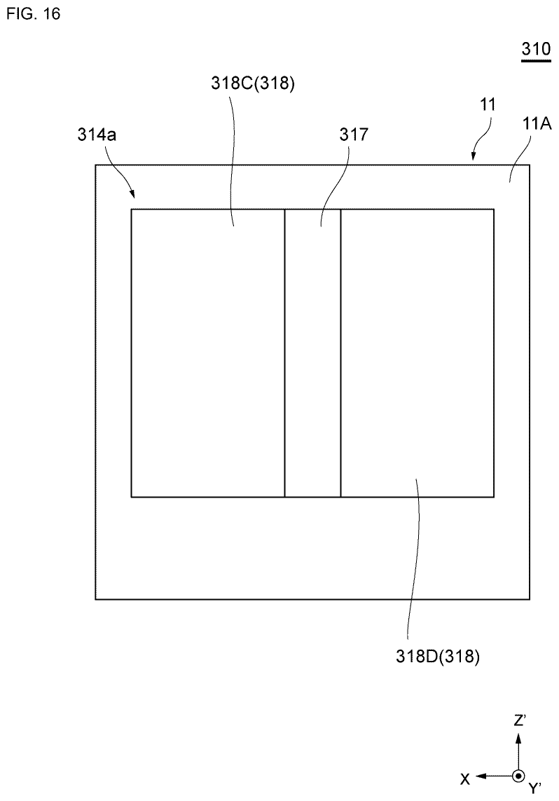

Next, the configuration of the quartz crystal resonator 310 according to the third embodiment will be described with reference to FIG. 16. FIG. 16 is a plan view of the quartz crystal resonator according to the third embodiment.

As illustrated in FIG. 16, the quartz crystal resonator 310 includes a high acoustic velocity region 317, a third low acoustic velocity region 318C, and a fourth low acoustic velocity region 318D. In plan view, the high acoustic velocity region 317 is provided in a region that is the center portion of the first excitation electrode 314a in the X axis direction and extends in the Z′ axis direction. The third low acoustic velocity region 318C is provided in a region that is adjacent to the high acoustic velocity region 317 in the positive X axis direction and extends in the Z′ axis direction. The fourth low acoustic velocity region 318D is provided in a region that is adjacent to the high acoustic velocity region 317 in the negative X axis direction and extends in the Z′ axis direction. In plan view, the high acoustic velocity region 317, the third low acoustic velocity region 318C, and the fourth low acoustic velocity region 318D extend from the end portion of the first excitation electrode 314a in the negative Z′ axis direction to the end portion of the first excitation electrode 314a in the positive Z′ axis direction in a band shape.

### Fourth Embodiment

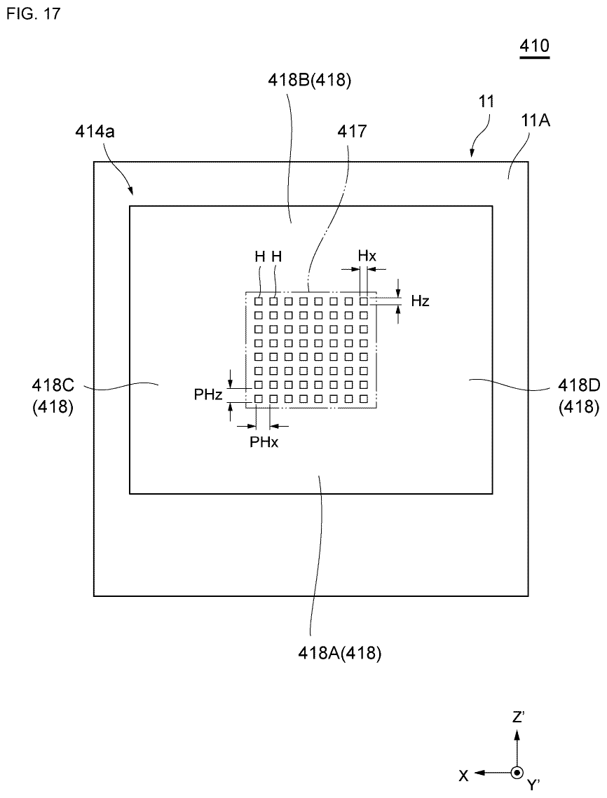

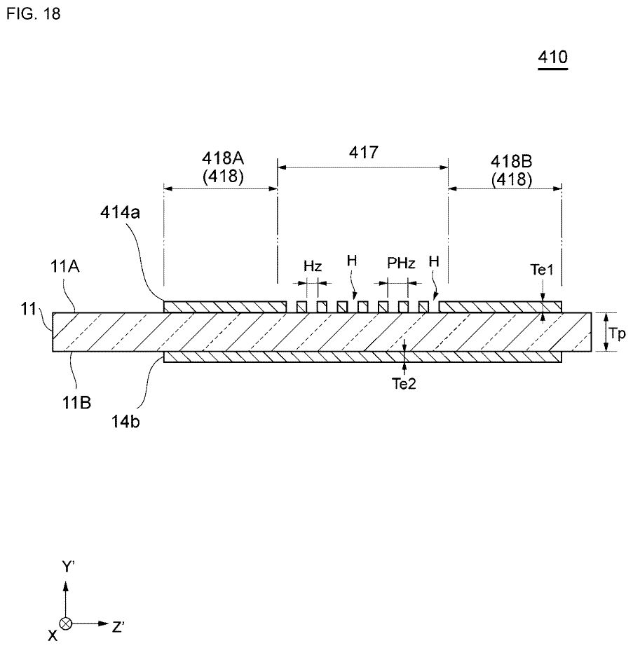

Next, the configuration of the quartz crystal resonator 410 according to the fourth embodiment will be described with reference to FIG. 17 and FIG. 18. FIG. 17 is a plan view of the quartz crystal resonator according to the fourth embodiment. FIG. 18 is a cross-sectional view of the quartz crystal resonator according to the fourth embodiment.

As illustrated in FIG. 17, the quartz crystal resonator 410 includes a high acoustic velocity region 417, a first low acoustic velocity region 418A, a second low acoustic velocity region 418B, a third low acoustic velocity region 418C, and a fourth low acoustic velocity region 418D. The thickness of the first excitation electrode 414a in the high acoustic velocity region 417 and the low acoustic velocity region 418 is Te1. In the high acoustic velocity region 417, a plurality of holes H are formed in the first excitation electrode 414a. The hole H is a through hole that penetrates the first excitation electrode 414a in the Y′ axis direction. Here, the hole is not limited to the through hole, and the hole may be a bottom groove shape that is open in the Y′ axis direction.

A dimension of the hole H in the Z′ axis direction is defined as Hz, and a dimension of the hole H in the X axis direction is defined as Hx. A planar shape of the hole H is a square shape having a side extending along the Z′ axis direction and a side extending along the X axis direction. That is, Hz=Hx.

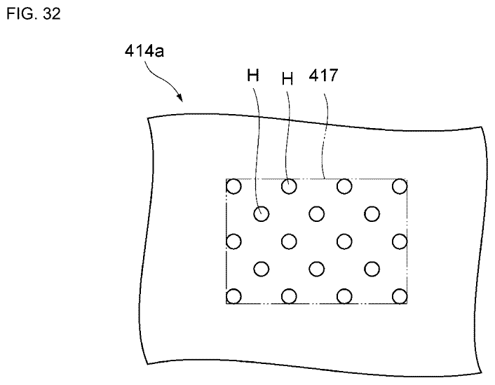

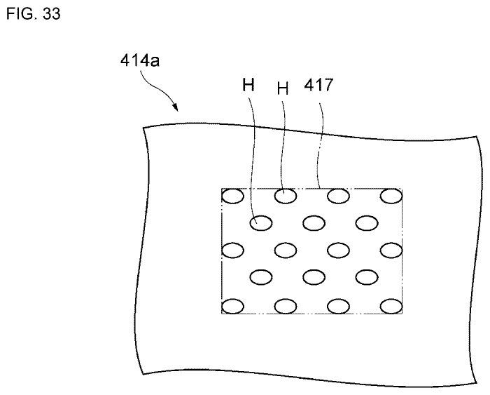

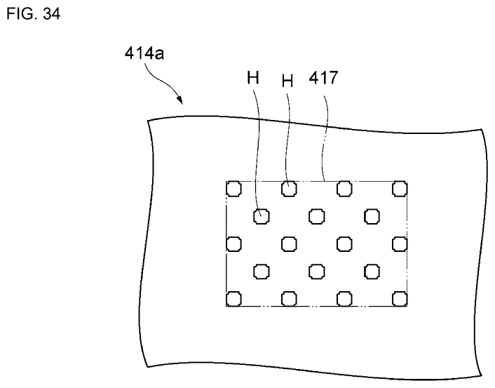

The planar shape of the hole H is not limited to a square shape having sides extending in the X axis direction and the Z′ axis direction. For example, the planar shape of the hole H may be a square shape having sides extending in a direction that intersects with the X axis direction and the Z′ axis direction, and may be a rectangular shape satisfying Hz<Hx or Hx<Hz. As illustrated in FIG. 32, the planar shape of the hole H may be a circular shape. As illustrated in FIG. 33, the planar shape of the hole H may be an elliptical shape. As illustrated in FIG. 34, the planar shape of the hole H may be a shape in which the four corners of a square shape are arced. In this way, the planar shape of the hole H may be a polygonal shape, a circular shape, an elliptical shape, or a combination thereof.

As illustrated in FIG. 17, the plurality of holes H are disposed in a matrix shape in the X axis direction and the X′ axis direction. A pitch of the plurality of holes H in the Z′ axis direction, that is, a distance between the end portions of two holes H, which are adjacent to each other in the Z′ axis direction and are on the negative Z′ axis direction side, is defined as PHz. A pitch of the holes H in the X axis direction, that is, a distance between the end portions of two holes H, which are adjacent to each other in the X axis direction and are on the negative X axis direction side, is defined as PHx. The plurality of holes H are disposed at equal intervals in each of the Z′ axis direction and the X axis direction. That is, PHz=PHx.

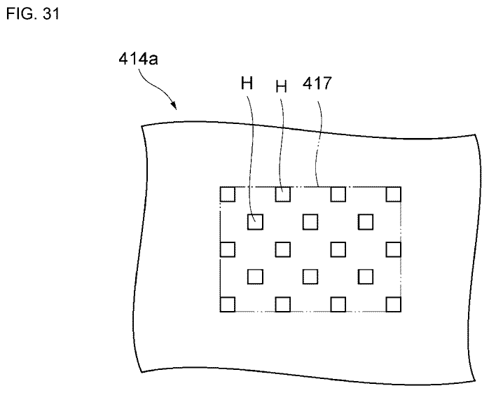

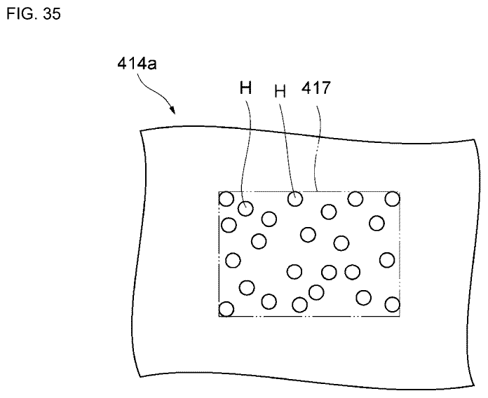

The pitch of the plurality of holes H is not limited to the pitch described above, and may be PHz<PHx or PHx<PHz. Further, the form in which the plurality of holes H are disposed is not limited to the form described above. The plurality of holes H may be disposed in a direction that intersects with the Z′ axis direction and the X axis direction. As illustrated in FIG. 31 to FIG. 34, the plurality of holes H may be disposed in a zigzag shape. As illustrated in FIG. 35, the plurality of holes H may be randomly disposed.

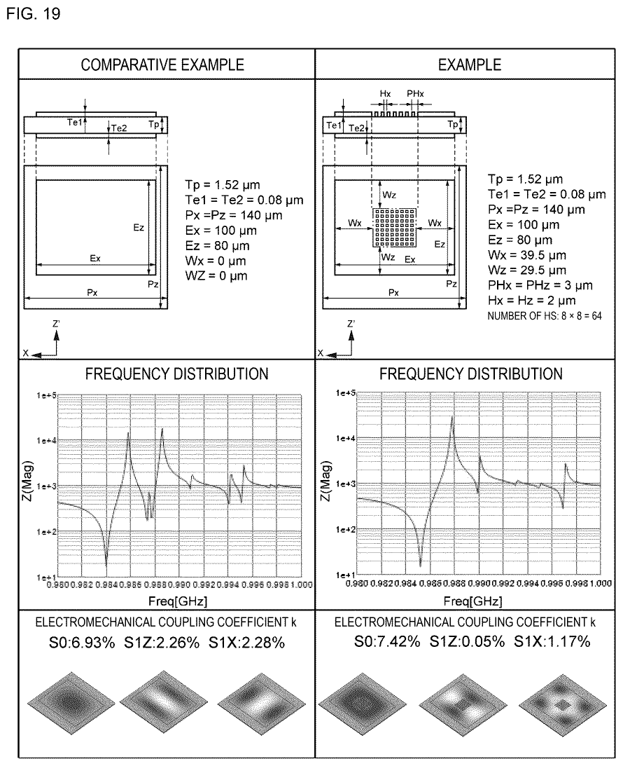

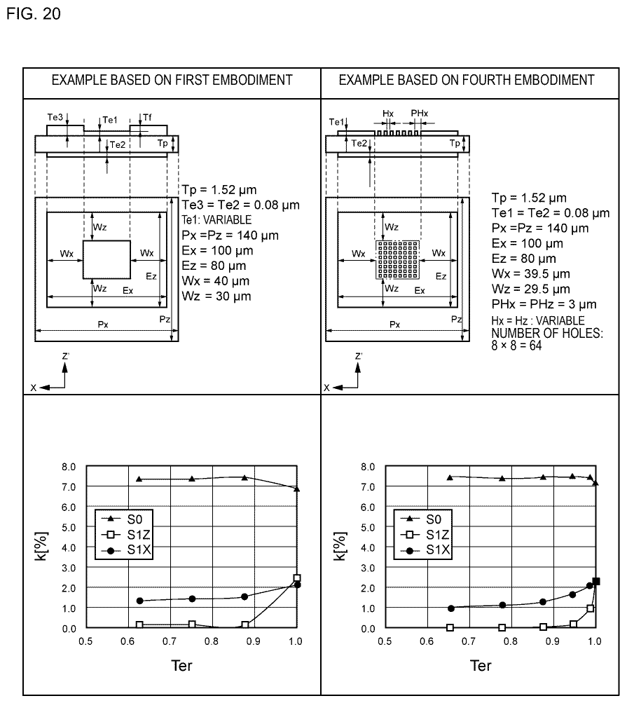

Next, simulation results of an example based on the fourth embodiment will be described with reference to FIG. 19 and FIG. 20. FIG. 19 is a diagram showing simulation results based on the fourth embodiment. FIG. 20 is a diagram showing comparison of simulation results based on the first embodiment and the fourth embodiment.

The configurations of the example and the comparative example in FIG. 19 are as follows.

### Example

$$Tp = 1.52 μm$$

$$Te 1 = Te 2 = 0.08 μm$$

$$Px = Pz = 140 μm$$

$$Ex = 100 μm$$

$$Ez = 80 μm$$

$$Wx = 39.5 μm$$

$$Wz = 29.5 μm$$

$$PHx = PHz = 3 μm$$

$$Hx = H z = 2 μm$$

$$Number of H : 8 \times 8 = 64$$

### Comparative Example

$$Tp = 1.52 μm$$

$$Te 1 = Te 2 = 0.08 μm$$

$$Px = Pz = 140 μm$$

$$Ex = 100 μm$$

$$Ez = 80 μm$$

$$Wx = 0 μm$$

$$Wz = 0 μm$$

As shown in the frequency distribution graph of FIG. 19, the frequency of the main mode in the example is approximately 985 MHz, and the frequency of the main mode in the comparative example is 984 MHz. In the example based on the first embodiment, the frequency is lower than in the comparative example. On the other hand, in the example based on the fourth embodiment, the frequency is higher than in the comparative example. This is because, in the first embodiment, the mass is added to the low acoustic velocity region to form a difference in acoustic velocity between the low acoustic velocity region and the high acoustic velocity region. On the other hand, this is because, in the fourth example, the mass in the high acoustic velocity region is reduced to form a difference in acoustic velocity between the low acoustic velocity region and the high acoustic velocity region. Therefore, in a case of increasing the frequency, the quartz crystal resonator 410 according to the fourth embodiment is advantageous.

As illustrated in FIG. 19, in the comparative example, k_S0=6.93%, k_S1Z=2.26%, and k_S1Z=2.28%. On the other hand, in the example, k_S0=7.42%, k_S1Z=0.05%, and k_S1X=1.17%. Therefore, in the example, the electromechanical coupling coefficient k_S0 of the main mode is improved, and the electromechanical coupling coefficients k_S1Z and k_S1X of the inharmonic mode are reduced.

The configurations of the example based on the first embodiment and the example based on the fourth embodiment illustrated in FIG. 20 are as follows. In the graph of FIG. 20, a horizontal axis Ter indicates a ratio of an average thickness of the excitation electrode in the high acoustic velocity region to the thickness of the excitation electrode in the low acoustic velocity region.

### Example Based on Fourth Embodiment

$$Tp = 1.52 μm$$

$$Te 1 = Te 2 = 0.08 μm$$

$$Px = Pz = 140 μm$$

$$Ex = 100 μm$$

$$Ez = 80 μm$$

$$Wx = 39.5 μm$$

$$Wz = 29.5 μm$$

$$PHx = PHz = 3 μm$$

$$Hx = H z : Variable$$

$$Number of H : 8 \times 8 = 64$$

### Example Based on First Embodiment

$$Tp = 1.52 μm$$

$$Te 3 ( = Te 1 + Tf ) = T e 2 = 0.08 μm$$

$$Te 1 : Variable$$

$$Px = Pz = 140 μm$$

$$Ex = 100 μm$$

$$Ez = 80 μm$$

$$Wx = 40 μm$$

$$Wz = 30 μm$$

In the example based on the fourth embodiment, Ter is represented by the following expression.

$$Ter = ( Te 1 h + Te 2 ) / ( Te 1 + Te 2 )$$

Te1h is the average thickness of the first excitation electrode in the high acoustic velocity region, and is represented by the following expression.

$$Te 1 h = Te 1 \times ( 1 - Har )$$

Har is an opening ratio of the plurality of holes H, and is represented by the following expression.

$$Har = ( H x / P Hx ) \times ( H z / PHz )$$

In the example based on the first embodiment, Ter is represented by the following expression.

$$Ter = ( Te 1 + Te 2 ) / ( T e 3 + T e 2 )$$

As illustrated in the graph of FIG. 20, tendencies of k_S0, k_S1Z, and k_S1X with respect to Ter in the example based on the fourth embodiment are substantially the same as the tendencies of k_S0, k_S1Z, and k_S1X with respect to Ter in the example based on the first embodiment. That is, in the fourth embodiment, it seems that the electromechanical coupling coefficient is improved by the same mechanism as that in the first embodiment.

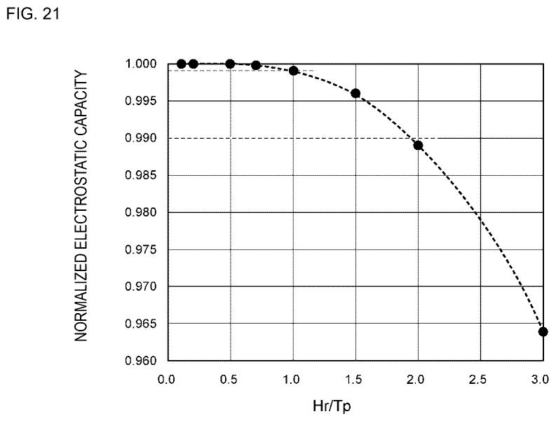

Next, an influence of the hole H on the function of the excitation electrode will be described with reference to FIG. 21. FIG. 21 is a graph showing an influence of the planar dimension of the hole. In the graph of FIG. 21, a horizontal axis indicates a ratio Hr/Tp of the length Hx=Hz=Hr of one side of the hole H of which the planar shape is a square shape to the thickness Tp of the quartz crystal element 11. In the graph of FIG. 21, a vertical axis indicates electrostatic capacity normalized by the electrostatic capacity in a state where the hole H is not formed.

When the length Hr of the hole H is 2 times or less the thickness Tp of the quartz crystal element 11, that is, when the relationship of 0<Hr/Tp≤2.0 is satisfied, a decrease rate of the electrostatic capacity is suppressed to 1% or less, and thus the first excitation electrode 414a can sufficiently function as an excitation electrode. According to some exemplary aspects, the length Hr of the hole H is 1.5 times or less the thickness Tp of the quartz crystal element 11, that is, the relationship of 0<Hr/Tp≤1.5 is satisfied. In some exemplary embodiments, the length Hr of the hole H is 1.0 or less the thickness Tp of the quartz crystal element 11, that is, the relationship of 0<Hr/Tp≤1.0 is satisfied. When 0<Hr/Tp≤1.5, the decrease rate of the electrostatic capacity can be suppressed to 0.5% or less, and when 0<Hr/Tp≤1.0, the decrease rate of the electrostatic capacity can be suppressed to 0.1% or less. In order to form the hole H with sufficient processing accuracy, according to some exemplary aspects, the length Hr of the hole His 0.1 times or more the thickness Tp of the quartz crystal element 11, that is, 0.1<Hr/Tp is satisfied. In some exemplary embodiments, the length Hr of the hole H is 0.5 times or more the thickness Tp of the quartz crystal element 11, that is, 0.5≤Hr/Tp is satisfied.

In a case where the planar shape of the hole H is a shape other than a square shape as illustrated in FIG. 32 to FIG. 35, the length Hr of the hole H is defined as a length of one side when the planar shape of the hole H is converted into a square shape while keeping the area constant. Even in such a case, as in the case where the planar shape of the hole H is a square shape, when the relationship of 0<Hr/Tp≤2.0 is satisfied, a decrease rate of the electrostatic capacity is suppressed to 1% or less, and thus the first excitation electrode 414a can sufficiently function as an excitation electrode. Further, as in the case where the planar shape of the hole H is a square shape, when 0<Hr/Tp≤1.5, the decrease rate of the electrostatic capacity can be suppressed to 0.5% or less, and when 0<Hr/Tp≤1.0, the decrease rate of the electrostatic capacity can be suppressed to 0.1% or less.

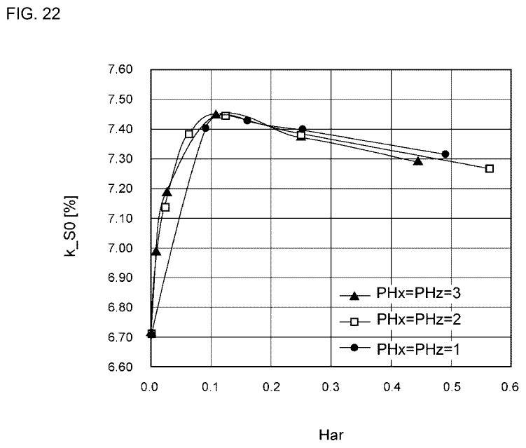

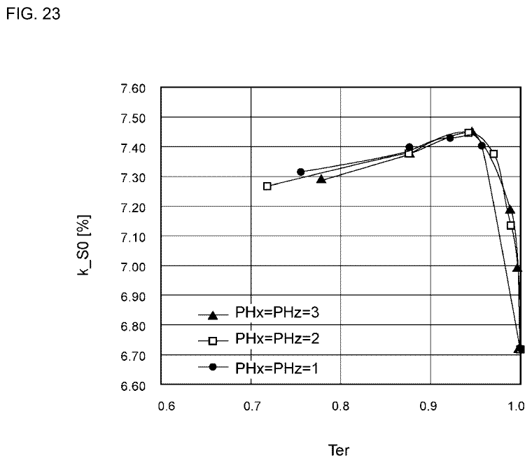

Next, influences of the pitches PHz and PHx of the plurality of holes H will be described with reference to FIG. 22 and FIG. 23. FIG. 22 and FIG. 23 are graphs showing influences of the planar dimensions and the pitches of the holes. In the graph of FIG. 22, a horizontal axis is Har described above. In the graph of FIG. 23, a horizontal axis is Ter described above. In FIG. 22 and FIG. 23, a vertical axis is k_S0 calculated under the following conditions.

$$Tp = 1. μm$$

$$Te 1 = Te 2 = 0.05 μm$$

$$Px = Pz = 100 μm$$

$$Ex = 75 μm$$

$$Ez = 70 μm$$

$$Wx = 30 μm$$

$$Wz = 20 μm$$

$$PHx = PHz : Variable$$

$$Hx = H z : Variable$$

As shown in FIG. 22, in all cases of PHz=PHx=3 μm, 2 μm, and 1 μm, k_S0 shows the same tendency with respect to Har. Further, as shown in FIG. 23, in all cases of PHz=PHx=3 μm, 2 μm, and 1 μm, k_S0 shows the same tendency with respect to Ter. That is, the electromechanical coupling coefficient k_S0 of the main mode is determined by Har and Ter not by the pitches PHz and PHx of the plurality of holes H. According to the graph of FIG. 22, k_S0 becomes maximum when the relationship of Har=0.1±0.05 is satisfied. According to the graph of FIG. 23, k_S0 becomes maximum when the relationship of Ter=0.93±0.03 is satisfied.

According to the present exemplary embodiment, the high acoustic velocity region 417 and the low acoustic velocity region 418 can be formed by the first excitation electrode 414a having a single layer structure. In a case of a configuration in which a first metal film having a uniform thickness is provided in a high acoustic velocity region and a low acoustic velocity region and then a second metal film is provided to form a low acoustic velocity region, a configuration in which a low acoustic velocity region is formed by providing a mass addition film made of an insulator, or the like, there is a case where a low acoustic velocity region having a desired width cannot be formed due to manufacturing variations caused by positional deviations of the second metal film and the mass addition film. On the other hand, according to the present exemplary embodiment, even when positional deviations of the plurality of holes H occur, by simply changing the position of the high acoustic velocity region 417, it is possible to form a low acoustic velocity region 418 having a desired width.

### Fifth Embodiment

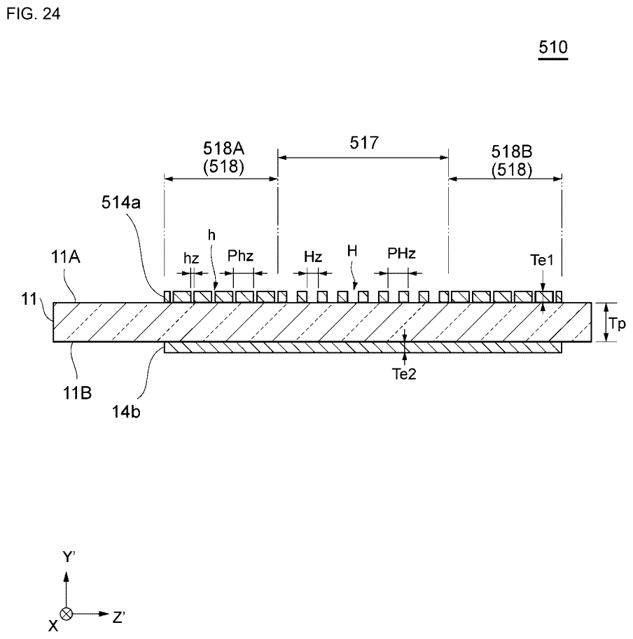

Next, a configuration of the quartz crystal resonator 510 according to the fifth embodiment will be described with reference to FIG. 24. FIG. 24 is a cross-sectional view of the quartz crystal resonator according to the fifth embodiment.

The thickness of the first excitation electrode 514a in the high acoustic velocity region 517 and the low acoustic velocity region 518 is Te1. In the high acoustic velocity region 717, a plurality of holes H are formed in the first excitation electrode 514a. In the low acoustic velocity region 718, a plurality of sub holes h are formed in the first excitation electrode 514a. The sub hole h is a through hole that penetrates the first excitation electrode 514a in the Y′ axis direction. Here, the sub hole h is not limited to the through hole, and may be a bottom groove shape that is open in the Y′ axis direction.

A dimension of the sub hole h in the Z′ axis direction is defined as hz, and a dimension of the sub hole h in the X axis direction is defined as hx. A planar shape of the sub hole h is a square shape having a side extending along the Z′ axis direction and a side extending along the X axis direction. That is, hz=hx. Here, the planar shape of the sub hole h is not limited to a square shape, and may be a rectangular shape satisfying hz<hx or a rectangular shape satisfying hx<hz. The planar shape of the sub hole h may be a polygonal shape, a circular shape, an elliptical shape, or a combination thereof.

A pitch of the plurality of sub holes h in the Z′ axis direction, that is, a distance between the end portions of two sub holes h, which are adjacent to each other in the Z′ axis direction and are on the negative Z′ axis direction side, is defined as Phz. A pitch of the sub holes h in the X axis direction, that is, a distance between the end portions of two sub holes h, which are adjacent to each other in the X axis direction and are on the negative X axis direction side, is defined as Phx. The plurality of sub holes h are disposed at equal intervals in each of the Z′ axis direction and the X axis direction. That is, Phz=Phx. Here, the pitch of the plurality of sub holes h is not limited to the pitch described above, and may be Phz<Phx or Phx<Phz. Further, the direction in which the plurality of sub holes h are disposed is not limited to the Z′ axis direction and the X axis direction, and the plurality of sub holes h may be disposed in a direction that intersects with the Z′ axis direction and the X axis direction. The plurality of sub holes h may be disposed in a zigzag shape.

In plan view, an area hz×hx of the sub hole h is smaller than an area Hz×Hx of the hole H. The pitch Phz of the plurality of sub holes h is substantially equivalent to the pitch PHz of the plurality of holes H (Phz≈PHz). In addition, the pitch Phx of the plurality of sub holes h is substantially equivalent to the pitch PHx of the plurality of holes H (Phx≈PHx).

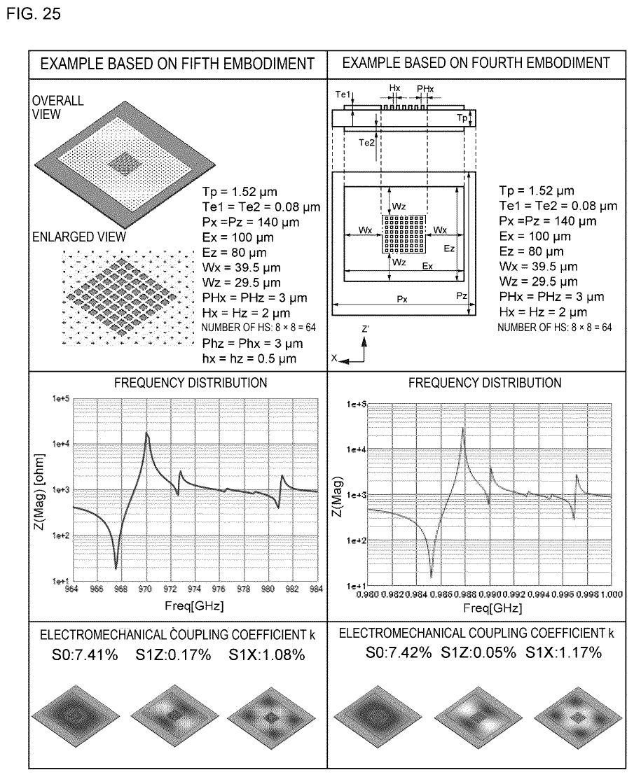

Next, simulation results of an example based on the fifth embodiment will be described with reference to FIG. 25. FIG. 25 is a diagram showing comparison of simulation results based on the fourth embodiment and the fifth embodiment.

The configuration of the example based on the fifth embodiment is as follows.

$$Tp = 1.52 μm$$

$$Te 1 = Te 2 = 0.08 μm$$

$$Px = Pz = 140 μm$$

$$Ex = 100 μm$$

$$Ez = 80 μm$$

$$Wx = 39.5 μm$$

$$Wz = 29.5 μm$$

$$PHx = PHz = 3 μm$$

$$Hx = H z = 2 μm$$

$$Number of H : 8 \times 8 = 64$$

$$Phz = Phx = 3 μm$$

$$hx = h z = 0.5 μm$$

The configuration of the example based on the fourth embodiment is the same as the configuration of the example illustrated in FIG. 19, and is the same as the configuration of the example based on the fifth embodiment, except that a plurality of sub holes h are not formed.

In the example based on the fifth embodiment, k_S0=7.41%, k_S1Z=0.17%, and k_S1Z=1.08%. In the example based on the fifth embodiment, similarly to the example based on the fourth embodiment, the electromechanical coupling coefficient k_S0 of the main mode is improved, and the electromechanical coupling coefficients k_S1Z and k_S1X of the inharmonic mode are reduced.

According to the present exemplary embodiment, by adjusting a ratio between the opening ratio Har of the plurality of holes H and the opening ratio har of the plurality of sub holes h, a ratio between the acoustic velocity of the high acoustic velocity region 517 and the acoustic velocity of the low acoustic velocity region 518 can be appropriately adjusted.

As long as the relationship of har<Har for the opening ratio har of the sub holes h and the opening ratio Har of the holes H is satisfied, the dimensions hz and hx and the pitches Phx and Phz of the sub holes h are not limited to the dimensions and the pitches described above. The opening ratio har is represented by the following expression.

$$har = ( h x / P hx ) \times ( hz / Phz )$$

For example, as long as the relationship of har<Har is satisfied, the pitch Phz of the sub holes h may be smaller than the pitch PHz of the holes H (Phz<PHz), and the pitch Phx of the sub holes h may be smaller than the pitch PHx of the holes H (Phx<PHx). At this time, in order to satisfy the relationship of har<Har, the area hz×hx of the sub hole h is smaller than the area Hz×Hx of the hole H (hz×hx<Hz×Hx).

For example, as long as the relationship har<Har is satisfied, the area hz×hx of the sub hole h may be equal to or larger than the area Hz×Hx of the hole H (Hz×Hx≤hz×hx). At this time, in order to satisfy the relationship of har<Har, at least one of a relationship in which the pitch Phz of the sub holes h is larger than the pitch PHz of the holes H (PHz<Phz) or a relationship in which the pitch Phx of the sub holes h is larger than the pitch PHx of the holes H (PHx<Phx) is satisfied.

Here, even in a case where the area hz×hx of the sub hole h is larger than the area Hz×Hx of the hole H (Hz×Hx<hz×hx), the length hz=hx=hr of one side of the sub hole h satisfies the relationship of 0<hr/Tp≤2.0, similarly to the length Hz=Hx=Hr of one side of the hole H. Thereby, the decrease rate of the electrostatic capacity is suppressed to 1% or less, and thus the low acoustic velocity region 518 can function as an excitation electrode. When 0<hr/Tp≤1.5, the decrease rate of the electrostatic capacity can be suppressed to 0.5% or less, and when 0<Hr/Tp≤1.0, the decrease rate of the electrostatic capacity can be suppressed to 0.1% or less.

### Sixth Embodiment

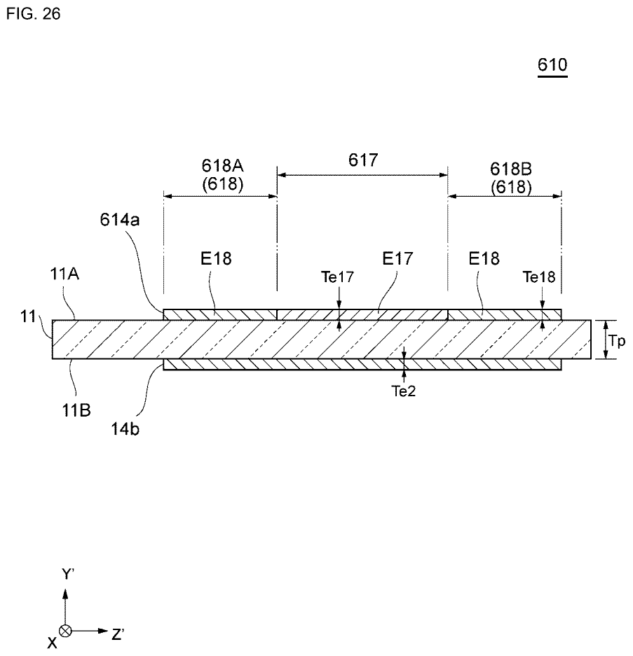

Next, a configuration of the quartz crystal resonator 610 according to the sixth embodiment will be described with reference to FIG. 26. FIG. 26 is a cross-sectional view of the quartz crystal resonator according to the sixth embodiment.

The first excitation electrode 614a includes a high acoustic velocity electrode E17 provided in the high acoustic velocity region 617 and low acoustic velocity electrodes E18 provided in the low acoustic velocity regions 618. The high acoustic velocity electrode E17 and the low acoustic velocity electrode E18 are continuous in the Z′ axis direction and the X axis direction. A thickness Te17 of the high acoustic velocity electrode E17 is substantially equal to a thickness Te18 of the low acoustic velocity electrode E18 (Te17≈Te18). The material of the high acoustic velocity electrode E17 is different from the material of the low acoustic velocity electrode E18. A specific gravity of the low acoustic velocity electrode E18 is larger than a specific gravity of the high acoustic velocity electrode E17.

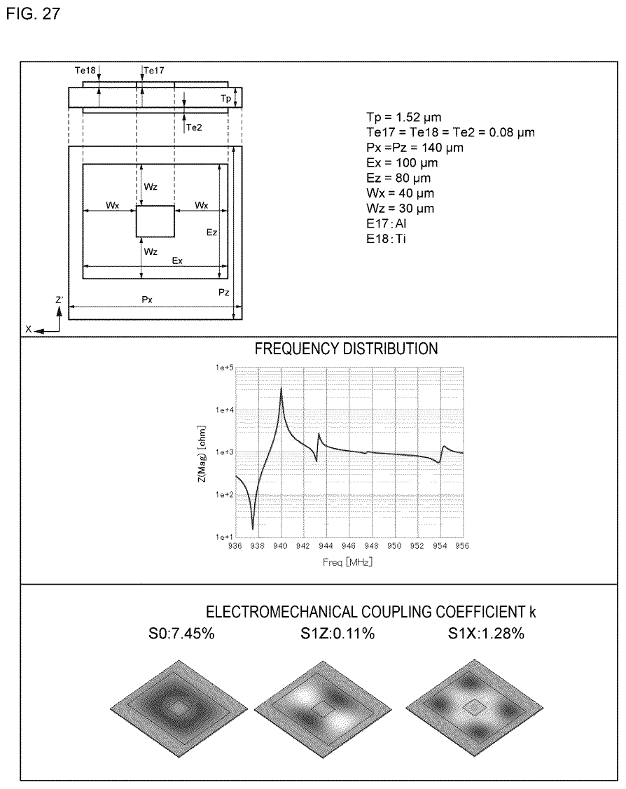

Next, simulation results of an example based on the sixth embodiment will be described with reference to FIG. 27. FIG. 27 is a diagram showing simulation results based on the sixth embodiment.

The configuration of the example based on the sixth embodiment is as follows.

$$Tp = 1.52 μm$$

$$Te 17 = Te 18 = T e 2 = 0.08 μm$$

$$Px = Pz = 140 μm$$

$$Ex = 100 μm$$

$$Ez = 80 μm$$

$$Wx = 40 μm$$

$$Wz = 30 μm$$

$$E 17 : Al$$

$$E 18 : Ti$$

As shown in the graph of the frequency distribution of FIG. 27, the frequency of the main mode is approximately 937.5 MHz. Further, as shown in FIG. 27, in the example based on the sixth embodiment, k_S0=7.45%, k_S1Z=0.11%, and k_S1X=1.28%.

### Seventh Embodiment

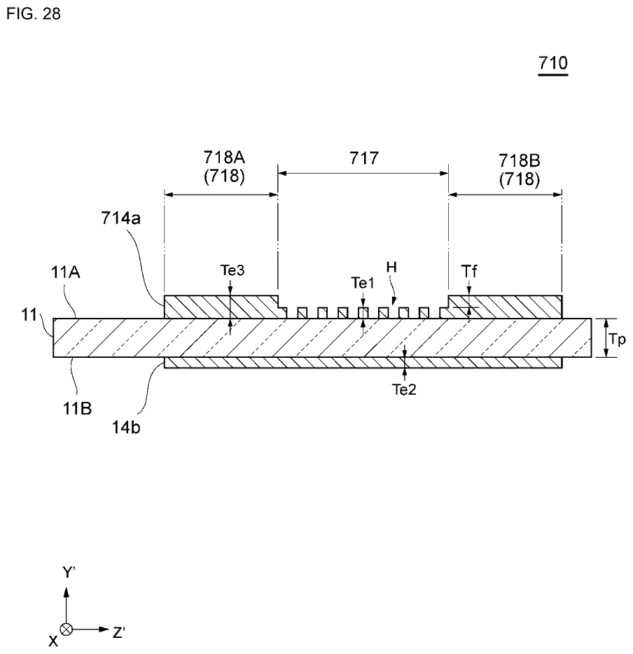

Next, a configuration of the quartz crystal resonator 710 according to the seventh embodiment will be described with reference to FIG. 28. FIG. 28 is a cross-sectional view of the quartz crystal resonator according to the seventh embodiment.

A thickness Te1 of the first excitation electrode 714a in the high acoustic velocity region 717 is thinner than a thickness Te3 of the first excitation electrode 714a in the low acoustic velocity region 718. That is, the relationship of Te3=Te1+Tf is satisfied. In the high acoustic velocity region 717, a plurality of holes H are formed in the first excitation electrode 714a.

According to the present exemplary embodiment, the thickness Te3 of the first excitation electrode 714a in the low acoustic velocity region 718 is thicker than the thickness Te1 of the first excitation electrode 714a in the high acoustic velocity region 717 by Tf, and thus the acoustic velocity of the low acoustic velocity region 718 is decreased. Further, the plurality of holes H are formed in the first excitation electrode 714a in the high acoustic velocity region 717, and thus the acoustic velocity of the high acoustic velocity region 717 is increased. That is, a difference in the acoustic velocity between the high acoustic velocity region 717 and the low acoustic velocity region 718 is further increased.

### Eighth Embodiment

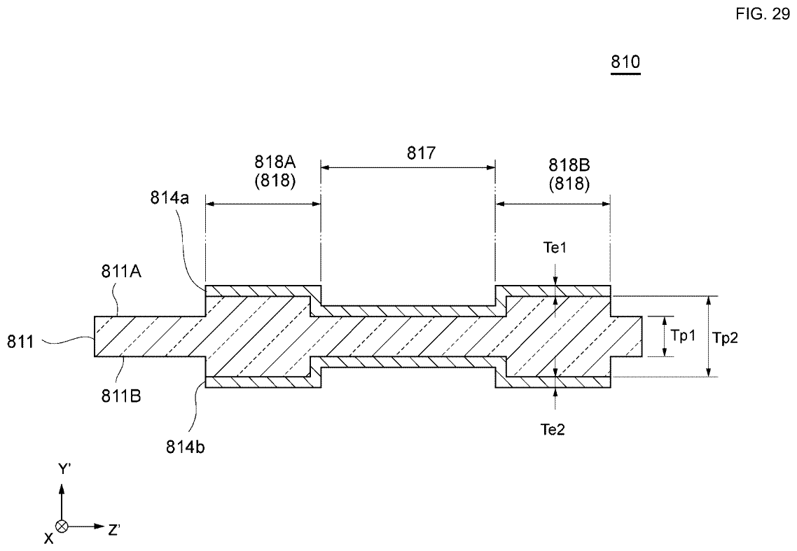

Next, a configuration of the quartz crystal resonator 810 according to the eighth embodiment will be described with reference to FIG. 29. FIG. 29 is a cross-sectional view of the quartz crystal resonator according to the eighth embodiment.

A thickness Tp2 of the quartz crystal element 811 in the low acoustic velocity region 818 is thicker than a thickness Tp1 of the quartz crystal element 811 in the high acoustic velocity region 817. That is, the quartz crystal element 811 is formed in an inverted mesa shape in a region overlapping the first excitation electrode 814a in plan view. The acoustic velocity of the low acoustic velocity region 818 is lower than the acoustic velocity of the high acoustic velocity region 817 by the difference Tp2-Tp1 in the thickness of the quartz crystal element 811.

### Ninth Embodiment

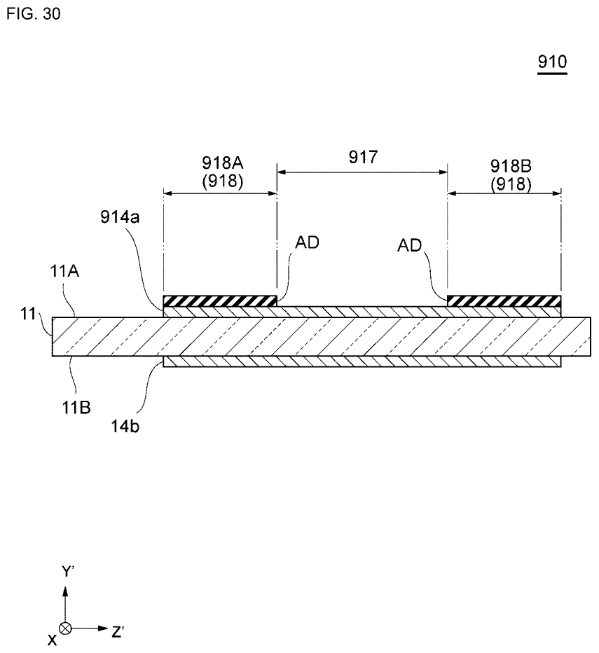

Next, a configuration of the quartz crystal resonator 910 according to the ninth embodiment will be described with reference to FIG. 30. FIG. 30 is a cross-sectional view of the quartz crystal resonator according to the ninth embodiment.

A mass addition film AD is provided on the first excitation electrode 914a in the low acoustic velocity region 918. In plan view, the mass addition film AD is provided in a region that is outside portion of the high acoustic velocity region 917 and overlaps the low acoustic velocity region 918. The mass addition film AD adds the mass to the low acoustic velocity region 918, and makes the mass per unit area of the low acoustic velocity region 918 in plan view larger than the mass per unit area of the high acoustic velocity region 917 in plan view. Thereby, the mass addition film AD decreases the acoustic velocity of the low acoustic velocity region 918. The material of the mass addition film AD is, for example, an insulator. From the viewpoint of efficiently decreasing the acoustic velocity of the low acoustic velocity region 918, according to some exemplary aspects, the material of the mass addition film is a material having a large specific gravity. For example, the specific gravity of the mass addition film is larger than the specific gravity of the first excitation electrode 914a.

The mass addition film AD is provided on the first excitation electrode 914a. On the other hand, the position of the mass addition film AD is not limited thereto as long as the mass addition film AD is provided in a region overlapping the first excitation electrode or the second excitation electrode in the low acoustic velocity region. The mass addition film may be provided at least one of a side of the first excitation electrode that is opposite to the quartz crystal element, a side of the first excitation electrode that is on the quartz crystal element side, a side of the second excitation electrode that is on the quartz crystal element side, or a side of the second excitation electrode that is opposite to the quartz crystal element. Further, the material of the mass addition film AD is an insulator, but is not limited thereto. The material of the mass addition film may be, for example, a metal different from the material of the first excitation electrode, or may be a semiconductor.

Some or all of the exemplary embodiments of the present disclosure will be appended below. The present disclosure is not limited to the following appendices.

According to some exemplary aspects, a piezoelectric resonator includes: a piezoelectric element; and an excitation electrode that overlaps the piezoelectric element in a thickness direction, in which the piezoelectric resonator includes a high acoustic velocity region and a low acoustic velocity region having an acoustic velocity lower than an acoustic velocity of the high acoustic velocity region, the high acoustic velocity region is provided in a region that overlaps a center portion of the excitation electrode in plan view in the thickness direction, the low acoustic velocity region includes a first low acoustic velocity region and a second low acoustic velocity region that are provided in regions overlapping end portions of the excitation electrode and surrounding the high acoustic velocity region in plan view in the thickness direction, in a first direction that intersects with the thickness direction, the first low acoustic velocity region is adjacent to the high acoustic velocity region, and the second low acoustic velocity region is adjacent to the high acoustic velocity region on a side opposite to the first low acoustic velocity region, and assuming that a length of the excitation electrode in the first direction is Ea, a length of the first low acoustic velocity region in the first direction is Wa1, and a length of the second low acoustic velocity region in the first direction is Wa2, relationships of

$$0.2 \leq Wa 1 / Ea ,$$

$$0.2 \leq Wa 2 / Ea , and$$

$$0.5 \leq ( Wa 1 + Wa 2 ) / Ea \leq 0.96$$

are satisfied.

According to some exemplary aspects, in the piezoelectric resonator, relationships of

$$0.25 \leq Wa 1 / Ea \leq 0.48 , and$$

$$0.25 \leq Wa 2 / Ea \leq 0.48$$

are satisfied.

According to some exemplary aspects, in the piezoelectric resonator, the low acoustic velocity region includes a third low acoustic velocity region and a fourth low acoustic velocity region that are provided in regions overlapping end portions of the excitation electrode and surrounding the high acoustic velocity region in plan view in the thickness direction, in a second direction that intersects with the thickness direction and the first direction, the third low acoustic velocity region is adjacent to the high acoustic velocity region, and the fourth low acoustic velocity region is adjacent to the high acoustic velocity region on a side opposite to the third low acoustic velocity region, and assuming that a length of the excitation electrode in the second direction is Eb, a length of the third low acoustic velocity region in the second direction is Wb1, and a length of the fourth low acoustic velocity region in the second direction is Wb2, relationships of

$$0.2 \leq W b 1 / Eb ,$$

$$0.2 \leq W b 2 / Eb , and$$

$$0.5 \leq ( W b 1 + W b 2 ) / Eb \leq 0.96$$

are satisfied.

According to some exemplary aspects, in the piezoelectric resonator, relationships of

$$0.25 \leq Wb 1 / Eb \leq 0.48 , and$$

$$0.25 \leq Wb 2 / Eb \leq 0.48$$

are satisfied.

According to some exemplary aspects, a piezoelectric resonator includes a piezoelectric element; and an excitation electrode, in which the piezoelectric resonator includes a high acoustic velocity region and a low acoustic velocity region having an acoustic velocity lower than an acoustic velocity of the high acoustic velocity region, the high acoustic velocity region is provided in a region that overlaps a center portion of the excitation electrode in plan view in a thickness direction, the low acoustic velocity region includes a first low acoustic velocity region, a second low acoustic velocity region, a third low acoustic velocity region, and a fourth low acoustic velocity region that are provided in regions overlapping end portions of the excitation electrode and surrounding the high acoustic velocity region in plan view in the thickness direction, in a first direction that intersects with the thickness direction, the first low acoustic velocity region is adjacent to the high acoustic velocity region, and the second low acoustic velocity region is adjacent to the high acoustic velocity region on a side opposite to the first low acoustic velocity region, in a second direction that intersects with the thickness direction and the first direction, the third low acoustic velocity region is adjacent to the high acoustic velocity region, and the fourth low acoustic velocity region is adjacent to the high acoustic velocity region on a side opposite to the third low acoustic velocity region, and assuming that a length of the excitation electrode in the first direction is Ea, a length of the excitation electrode in the second direction is Eb, a length of each of the first low acoustic velocity region and the second low acoustic velocity region in the first direction is Wa, and a length of each of the third low acoustic velocity region and the fourth low acoustic velocity region in the second direction is Wb, relationships of

$$0.8 < 5. \times {( Wa / Ea )}^{2} + 4. \times {( Wb / Eb )}^{2} ,$$

$$Wa / Ea \leq 0.48 , and$$

$$Wb / Eb \leq 0.48$$

are satisfied.

According to some exemplary aspects, in the piezoelectric resonator, in plan view in the thickness direction, one end portion of the first low acoustic velocity region in the second direction overlaps one end portion of the third low acoustic velocity region in the first direction, the other end portion of the first low acoustic velocity region in the second direction that is opposite to the one end portion overlaps one end portion of the fourth low acoustic velocity region in the first direction, one end portion of the second low acoustic velocity region in the second direction overlaps the other end portion of the third low acoustic velocity region in the first direction that is opposite to the one end portion, and the other end portion of the second low acoustic velocity region in the second direction that is opposite to the one end portion overlaps the other end portion of the fourth low acoustic velocity region in the first direction that is opposite to the one end portion.

According to some exemplary aspects, in the piezoelectric resonator, the first low acoustic velocity region and the second low acoustic velocity region extend along a second direction that intersects with the first direction in plan view, and assuming that a length of the excitation electrode in the second direction is Eb, a length of the first low acoustic velocity region in the second direction is Lb1, and a length of the first low acoustic velocity region in the second direction is Lb2, relationships of

$$0.8 \leq Lb 1 / Eb \leq 1. , and$$

$$0.8 \leq Lb 2 / Eb \leq 1.$$

are satisfied.

According to some exemplary aspects, in the piezoelectric resonator, the third low acoustic velocity region and the fourth low acoustic velocity region extend along the first direction in plan view, and assuming that a length of the third low acoustic velocity region in the first direction is La1 and a length of the fourth low acoustic velocity region in the first direction is La2, relationships of

$$0.8 \leq La 1 / Ea \leq 1. , and$$

$$0.8 \leq La 2 / Ea \leq 1.$$

are satisfied.

According to some exemplary aspects, in the piezoelectric resonator, assuming that a length of the excitation electrode in the first direction is Ea, a length of the excitation electrode in the second direction is Eb, a length of each of the first low acoustic velocity region and the second low acoustic velocity region in the first direction is Wa, and a length of each of the third low acoustic velocity region and the fourth low acoustic velocity region in the second direction is Wb, relationships of

$$Wa / Ea = 0.35 \pm 0.05 , and$$

$$Wb / Eb = 0.35 \pm 0.05$$

are satisfied.

According to some exemplary aspects, in the piezoelectric resonator, assuming that a length of the excitation electrode in the first direction is Ea, a length of the excitation electrode in the second direction is Eb, a length of each of the first low acoustic velocity region and the second low acoustic velocity region in the first direction is Wa, and a length of each of the third low acoustic velocity region and the fourth low acoustic velocity region in the second direction is Wb, relationships of

$$Wa / Ea = 0.4 \pm 0.05 , and$$

$$Wb / Eb = 0.4 \pm 0.05$$

are satisfied.

According to some exemplary aspects, in the piezoelectric resonator, a thickness of the excitation electrode in the low acoustic velocity region is thicker than a thickness of the excitation electrode in the high acoustic velocity region.

According to some exemplary aspects, the piezoelectric resonator further includes: a mass addition film that overlaps the excitation electrode in the low acoustic velocity region.

According to some exemplary aspects, in the piezoelectric resonator, a material of the mass addition film is a metal different from a material of the excitation electrode. According to some exemplary aspects, in the piezoelectric resonator, a material of the mass addition film is an insulator different from a material of the piezoelectric element.

According to some exemplary aspects, in the piezoelectric resonator, a plurality of holes are formed in the excitation electrode in the high acoustic velocity region.

According to some exemplary aspects, in the piezoelectric resonator, the plurality of holes are through holes that penetrate the excitation electrode in the thickness direction, and assuming that a thickness of the piezoelectric element is Tp, that, in a case where a shape of each of the plurality of holes is a square shape in plan view, a length of one side of the square shape is Hr, and that, in a case where a shape of each of the plurality of holes is a shape other than a square shape in plan view, a length of one side of the shape when the shape is converted into a square shape while keeping an area constant is Hr, a relationship of 0<Hr/Tp≤2.0 is satisfied.

According to some exemplary aspects, in the piezoelectric resonator, a plurality of sub holes are formed in the excitation electrode in the low acoustic velocity region, an opening ratio of the plurality of sub holes is lower than an opening ratio of the plurality of holes, and assuming that a thickness of the piezoelectric element is Tp, that, in a case where a shape of each of the plurality of holes is a square shape in plan view, a length of one side of the square shape is hr, and that, in a case where a shape of each of the plurality of holes is a shape other than a square shape in plan view, a length of one side of the shape when the shape is converted into a square shape while keeping an area constant is hr, a relationship of 0<hr/Tp≤2.0 is satisfied.

According to some exemplary aspects, in the piezoelectric resonator, a material of the excitation electrode in the low acoustic velocity region is different from a material of the excitation electrode in the high acoustic velocity region, and a specific gravity of the excitation electrode in the low acoustic velocity region is larger than a specific gravity of the excitation electrode in the high acoustic velocity region.

According to some exemplary aspects, in the piezoelectric resonator, a thickness of the piezoelectric element in the low acoustic velocity region is thicker than a thickness of the piezoelectric element in the high acoustic velocity region.

According to some exemplary aspects, in the piezoelectric resonator, a main vibration mode is thickness shear vibration.

According to some exemplary aspects, in the piezoelectric resonator, the piezoelectric element is a quartz crystal element.

According to some exemplary aspects, in the piezoelectric resonator, a cut-angle of the quartz crystal element is an AT cut, a BT cut, or an ST cut.

The exemplary embodiments according to the present disclosure are not limited to a quartz crystal resonator unit, and can be applied to another piezoelectric resonator unit. As a piezoelectric element that is used for the piezoelectric resonator unit according to the present exemplary embodiment, for example, a piezoelectric ceramic such as PZT or aluminum nitride, a piezoelectric single crystal such as lithium niobate or lithium tantalate, and the like are used. On the other hand, the material of the piezoelectric element is not limited thereto, and can be selected as appropriate.

The exemplary embodiments according to the present disclosure are not particularly limited, and can be applied to any device that converts electromechanical energy using a piezoelectric effect, such as a timing device, a sound generator, an oscillator, or a load sensor.

As described above, according to an exemplary aspect of the present disclosure, a piezoelectric resonator is provide with an improved electromechanical coupling coefficient.

The exemplary embodiments described above are intended to facilitate understanding of the present disclosure, and are not intended to be interpreted as limiting the present disclosure. The present disclosure may be modified/improved without departing from the gist of the present disclosure, and the present disclosure also includes equivalents thereof. That is, the scope of the present disclosure includes designs obtained by appropriately changing the exemplary embodiments and/or the modification examples by those skilled in the art as long as the designs have the characteristics of the present disclosure. For example, each component included in the exemplary embodiments and/or the modification examples, arrangement, a material, a condition, a shape, a size, and the like of the component are not limited to those illustrated, and can be changed as appropriate. In addition, the exemplary embodiments and the modification examples are merely examples, and it goes without saying that partial substitutions or combinations of the configurations illustrated in the different embodiments and/or modification examples can be made, and substitutions or combinations are also included within the scope of the present disclosure as long as the substitutions or combinations include the characteristics of the present disclosure.

### REFERENCE SIGNS LIST

100 CRYSTAL OSCILLATOR
1 QUARTZ CRYSTAL RESONATOR UNIT
10 QUARTZ CRYSTAL RESONATOR
11 QUARTZ CRYSTAL ELEMENT
11A UPPER SURFACE
11B LOWER SURFACE
14a FIRST EXCITATION ELECTRODE
14b SECOND EXCITATION ELECTRODE
17 HIGH ACOUSTIC VELOCITY REGION
18 LOW ACOUSTIC VELOCITY REGION
18A FIRST LOW ACOUSTIC VELOCITY REGION
18B SECOND LOW ACOUSTIC VELOCITY REGION
18C THIRD LOW ACOUSTIC VELOCITY REGION
18D FOURTH LOW ACOUSTIC VELOCITY REGION

What is claimed:

1. A piezoelectric resonator, comprising:
a piezoelectric element; and
an excitation electrode that overlaps the piezoelectric element in a thickness direction of the piezoelectric element, the excitation electrode comprising:
a center portion in a plan view in the thickness direction, the center portion being configured to form a high acoustic velocity region in the piezoelectric resonator; and
a first end portion and a second end portion at opposite sides of the center portion in a first direction intersecting the thickness direction, the first end portion and the second end portion being configured to form a first low acoustic velocity region and a second low acoustic velocity region, respectively, on opposite sides of the high acoustic velocity region in the first direction;
wherein the excitation electrode is configured to have a first length of the excitation electrode (Ea) in the first direction, a length of the first low acoustic velocity region (Wa1) in the first direction, and a length of the second low acoustic velocity region (Wa2) in the first direction, that satisfy relationships of:
$$0.2 \leq Wa 1 / Ea ,$$
$$0.2 \leq Wa 2 / Ea , and$$
$$0.5 \leq ( Wa 1 + Wa 2 ) / Ea \leq 0.96 .$$

2. The piezoelectric resonator according to claim 1, wherein the excitation electrode is configured to satisfy relationships of:
$$0.25 \leq Wa 1 / Ea \leq 0.48 , and$$
$$0.25 \leq Wa 2 / Ea \leq 0.48 .$$

3. The piezoelectric resonator according to claim 1, wherein the excitation electrode comprises:
a third end portion and a fourth end portion at opposite sides of the center portion in a second direction intersecting the thickness direction and the first direction, the third end portion and the fourth end portion being configured to form a third low acoustic velocity region and a fourth low acoustic velocity region, respectively, on opposite sides of the high acoustic velocity region in the second direction;
wherein the excitation electrode is configured to have a second length of the excitation electrode (Eb) in the second direction, a length of the third low acoustic velocity region (Wb1) in the second direction, and a length of the fourth low acoustic velocity region (Wb2) in the second direction, that satisfy relationships of:
$$0.2 \leq Wb 1 / Eb ,$$
$$0.2 \leq Wb 2 / Eb , and$$
$$0.5 \leq ( Wb 1 + Wb 2 ) / Eb \leq 0.96 .$$

4. The piezoelectric resonator according to claim 3, wherein the excitation electrode is configured to satisfy relationships of:
$$0.25 \leq Wb 1 / Eb \leq 0.48 , and$$
$$0.25 \leq Wb 2 / Eb \leq 0.48 .$$

5. The piezoelectric resonator according to claim 3, wherein the excitation electrode is configured that in the plan view in the thickness direction:
a first end portion of the first low acoustic velocity region in the second direction overlaps a first end portion of the third low acoustic velocity region in the first direction;
a second end portion of the first low acoustic velocity region in the second direction that is opposite to the first end portion of the first acoustic velocity region in the second direction overlaps a first end portion of the fourth low acoustic velocity region in the first direction;
a first end portion of the second low acoustic velocity region in the second direction overlaps a second end portion of the third low acoustic velocity region in the first direction that is opposite to the first end portion of the third low acoustic velocity region in the first direction; and
a second end portion of the second low acoustic velocity region in the second direction that is opposite to the first end portion of the second low acoustic velocity region in the second direction overlaps a second end portion of the fourth low acoustic velocity region in the first direction that is opposite to the first end portion of the fourth low acoustic velocity region in the first direction.

6. The piezoelectric resonator according to claim 1, wherein the excitation electrode is configured that:
the first low acoustic velocity region and the second low acoustic velocity region extend along a second direction intersecting with the thickness direction and the first direction;
a second length of the excitation electrode in the second direction (Eb), a length of the first low acoustic velocity region in the second direction (Lb1), and a length of the first low acoustic velocity region in the second direction (Lb2), satisfy relationships of:
$$0.8 \leq Lb 1 / Eb \leq 1. , and$$
$$0.8 \leq Lb 2 / Eb \leq 1. .$$

7. The piezoelectric resonator according to claim 3, wherein the excitation electrode is configured that:
the third low acoustic velocity region and the fourth low acoustic velocity region extend along the first direction in the plan view in the thickness direction; and
a length of the third low acoustic velocity region in the first direction (La1) and a length of the fourth low acoustic velocity region in the first direction (La2) satisfy relationships of:
$$0.8 \leq La 1 / Ea \leq 1. , and$$
$$0.8 \leq La 2 / Ea \leq 1. .$$

8. The piezoelectric resonator according to claim 3, wherein the excitation electrode is configured that:
the length of the excitation electrode in the first direction (Ea), the length of the excitation electrode in the second direction (Eb), a length of each of the first low acoustic velocity region and the second low acoustic velocity region in the first direction (Wa), and a length of each of the third low acoustic velocity region and the fourth low acoustic velocity region in the second direction (Wb) satisfy relationships of:
$$Wa / Ea = 0.35 \pm 0.05 , and$$
$$Wb / Eb = 0.35 \pm 0.05 .$$

9. The piezoelectric resonator according to claim 3, wherein the excitation electrode is configured that:
the length of the excitation electrode in the first direction (Ea), the length of the excitation electrode in the second direction (Eb), a length of each of the first low acoustic velocity region and the second low acoustic velocity region in the first direction (Wa), and a length of each of the third low acoustic velocity region and the fourth low acoustic velocity region in the second direction (Wb), satisfy relationships of:
$$Wa / Ea = 0.4 \pm 0.05 , and$$
$$Wb / Eb = 0.4 \pm 0.05 .$$

10. The piezoelectric resonator according to claim 1, wherein a thickness of the excitation electrode in the low acoustic velocity region is thicker than a thickness of the excitation electrode in the high acoustic velocity region.

11. The piezoelectric resonator according to claim 1, further comprising a mass addition film that overlaps the excitation electrode in the low acoustic velocity region.

12. The piezoelectric resonator according to claim 11, wherein a material of the mass addition film is a metal different from a material of the excitation electrode.

13. The piezoelectric resonator according to claim 11, wherein a material of the mass addition film is an insulator different from a material of the piezoelectric element.

14. The piezoelectric resonator according to claim 1, wherein the excitation electrode comprises a plurality of holes formed in the high acoustic velocity region.

15. The piezoelectric resonator according to claim 14, wherein:
the plurality of holes are through holes that penetrate the excitation electrode in the thickness direction; and
a thickness of the piezoelectric element (Tp) and a size of each of the plurality of holes (Hr) satisfy a relationship of 0<Hr/Tp≤2.0.

16. The piezoelectric resonator according to claim 14, wherein:
the excitation electrode has a plurality of sub holes formed in the low acoustic velocity region, an opening ratio of the plurality of sub holes is lower than an opening ratio of the plurality of holes; and
a thickness of the piezoelectric element (Tp), a size of each of the plurality of holes (hr) satisfy a relationship of 0<hr/Tp≤2.0.

17. The piezoelectric resonator according to claim 1, wherein:
a material of the excitation electrode in the low acoustic velocity region is different from a material of the excitation electrode in the high acoustic velocity region; and
a specific gravity of the excitation electrode in the low acoustic velocity region is larger than a specific gravity of the excitation electrode in the high acoustic velocity region.

18. The piezoelectric resonator according to claim 1, wherein a thickness of the piezoelectric element in the low acoustic velocity region is thicker than a thickness of the piezoelectric element in the high acoustic velocity region.

19. The piezoelectric resonator according to claim 1, wherein a main vibration mode of the piezoelectric resonator is thickness shear vibration.

20. A piezoelectric resonator, comprising:
a piezoelectric element; and
an excitation electrode that overlaps the piezoelectric element in a thickness direction of the piezoelectric element, the excitation electrode comprising:
a center portion in a plan view in the thickness direction, the center portion being configured to form a high acoustic velocity region in the piezoelectric resonator;
a first end portion and a second end portion at opposite sides of the center portion in a first direction intersecting the thickness direction, the first end portion and the second end portion being configured to form a first low acoustic velocity region and a second low acoustic velocity region, respectively, on opposite sides of the high acoustic velocity region in the first direction with a lower acoustic velocity than the high acoustic velocity region;
a third end portion and a fourth end portion at opposite sides of the center portion in a second direction intersecting the thickness direction, the third end portion and the fourth end portion being configured to form a third low acoustic velocity region and a fourth low acoustic velocity region, respectively, on opposite sides of the high acoustic velocity region in the second direction with a lower acoustic velocity than the high acoustic velocity region;
wherein the excitation electrode has a first length of the excitation electrode (Ea) in the first direction, a second length of the excitation electrode in the second direction (Eb), a length of each of the first low acoustic velocity region and the second low acoustic velocity region in the first direction (Wa), and a length of each of the third low acoustic velocity region and the fourth low acoustic velocity region in the second direction (Wb), that satisfy relationships of:
$$0.8 < 5. \times {( Wa / Ea )}^{2} + 4. \times {( Wb / Eb )}^{2} ,$$
$$Wa / Ea \leq 0.48 , and$$
$$Wb / Eb \leq 0.48 .$$
